(19) United States
(12) Patent Application Publication
(10) Pub. No.: US 2026/0266893 A1
(43) Pub. Date: Sep. 10, 2026

(54) ELECTRONIC APPARATUS, PRINT HEAD, AND METHOD FOR MANUFACTURING ELECTRONIC APPARATUS

(71) Applicant: SEIKO EPSON CORPORATION, Tokyo (JP)

(72) Inventors: Hidekazu UEMATSU, Fujimi-machi (JP); Toru MATSUYAMA, Matsumoto (JP)

(21) Appl. No.: 19/555,016

(22) Filed: Mar. 3, 2026

(30) Foreign Application Priority Data
Mar. 5, 2025 (JP) 2025-034742

(51) Int. Cl. G01R 31/28; G01R 31/56

(52) U.S. Cl. CPC G01R 31/2818; G01R 31/56

(57) ABSTRACT

An electronic apparatus includes a circuit substrate. The circuit substrate includes: a signal through-hole through which an electrical signal for driving the electronic apparatus is supplied; a reference through-hole set to a reference electrical potential; and a first inspection through-hole to which a signal is not supplied when the electronic apparatus is used. A distance between the reference through-hole and the first inspection through-hole is shorter than a distance between the reference through-hole and the signal through-hole.

The present application is based on, and claims priority from JP Application Serial Number 2025-034742, filed Mar. 5, 2025, the disclosure of which is hereby incorporated by reference herein in its entirety.

### BACKGROUND

### 1. Technical Field

The present disclosure relates to an electronic apparatus, a print head, and a method for manufacturing an electronic apparatus.

### 2. Related Art

A so-called refurbishment technology is known in which a new electronic apparatus is manufactured by refurbishing a used electronic apparatus. For example, JP-A-2004-239944 discloses a technique for determining whether the product life of each of a plurality of components disposed on a circuit substrate included in an electronic apparatus has expired, based on a consumed current value of the circuit substrate, and for reusing a component whose product life has not yet expired.

However, according to the related art, since the degradation state of the circuit substrate is not inspected, there is a possibility that the circuit substrate is reused even though a defect occurs in the circuit substrate.

### SUMMARY

According to an aspect of the present disclosure, there is provided an electronic apparatus including a circuit substrate, wherein the circuit substrate includes a signal through-hole through which an electrical signal for driving the electronic apparatus is supplied, a reference through-hole set to a reference electrical potential, and a first inspection through-hole to which a signal is not supplied when the electronic apparatus is used, and a distance between the reference through-hole and the first inspection through-hole is shorter than a distance between the reference through-hole and the signal through-hole.

According to another aspect of the present disclosure, there is provided a print head including a circuit substrate, wherein the circuit substrate includes a signal through-hole through which an electrical signal for driving the print head is supplied, a reference through-hole set to a reference electrical potential, and a first inspection through-hole to which a signal is not supplied when the print head is used, and a distance between the reference through-hole and the first inspection through-hole is shorter than a distance between the reference through-hole and the signal through-hole.

According to still another aspect of the present disclosure, there is provided a method for manufacturing an electronic apparatus including a first circuit substrate, another electronic apparatus including a second circuit substrate having the same function as the first circuit substrate, the method including: if conduction between a reference through-hole disposed in the second circuit substrate and set to a reference electrical potential and a first inspection through-hole that is disposed in the second circuit substrate and to which a signal is not supplied when the other electronic apparatus is used is not confirmed, manufacturing the electronic apparatus by using the second circuit substrate as the first circuit substrate; and if the conduction between the reference through-hole and the first inspection through-hole is confirmed, manufacturing the electronic apparatus without using the second circuit substrate, wherein a distance between the reference through-hole and the first inspection through-hole is shorter than a distance between the reference through-hole and a signal through-hole through which an electrical signal for driving the electronic apparatus is supplied.

### BRIEF DESCRIPTION OF THE DRAWINGS

FIG. 1 is a schematic diagram illustrating an example of a configuration of a manufacturing management system according to an embodiment of the present disclosure.

FIG. 2 is a block diagram illustrating an example of a configuration of a management server.

FIG. 3 is a block diagram illustrating an example of a configuration of a printing apparatus.

FIG. 4 is a block diagram illustrating an example of a configuration of a drive signal generating circuit.

FIG. 5 is a perspective view illustrating an example of a structure of a drive control unit.

FIG. 6 is a plan view illustrating the example of the structure of the drive control unit.

FIG. 7 is a cross-sectional view illustrating an example of a structure of a circuit substrate.

FIG. 8 is a schematic diagram for explaining an example of a dendrite.

FIG. 9 is a schematic diagram for explaining an example of a dendrite.

FIG. 10 is a flowchart illustrating an example of an operation of the management server.

FIG. 11 is a flowchart illustrating the example of the operation of the management server.

FIG. 12 is a flowchart illustrating the example of the operation of the management server.

FIG. 13 is a flowchart illustrating the example of the operation of the management server.

FIG. 14 is a flowchart illustrating an example of an operation of the management server according to a first modification of the present disclosure.

FIG. 15 is a block diagram illustrating an example of a configuration of a projector according to a second modification of the present disclosure.

FIG. 16 is a perspective view illustrating an example of a structure of a display control unit.

### DESCRIPTION OF EMBODIMENTS

Hereinafter, embodiments for carrying out the present disclosure will be described with reference to the drawings. However, in each drawing, the dimensions and scale of each section are appropriately different from the actual ones. In addition, since the embodiments described below are suitable specific examples of the present disclosure, the embodiments include various technically preferable limitations, but the scope of the present disclosure is not limited to the embodiments unless otherwise stated in the following description to particularly limit the present disclosure.

### A. EMBODIMENTS

In the present embodiment, a manufacturing management system Sys for refurbishing a used printing apparatus 1 to manufacture a new printing apparatus 1 will be described as an example.

### A.1. Overview of Manufacturing Management System Sys

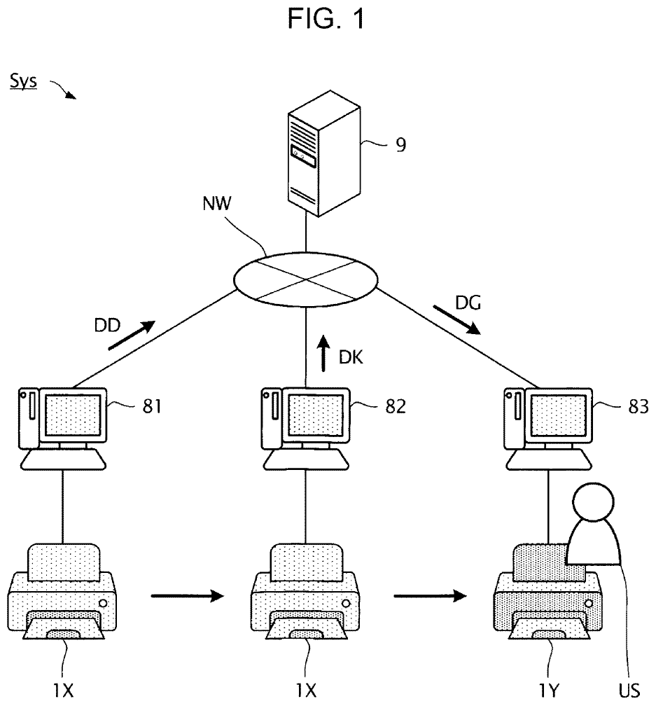

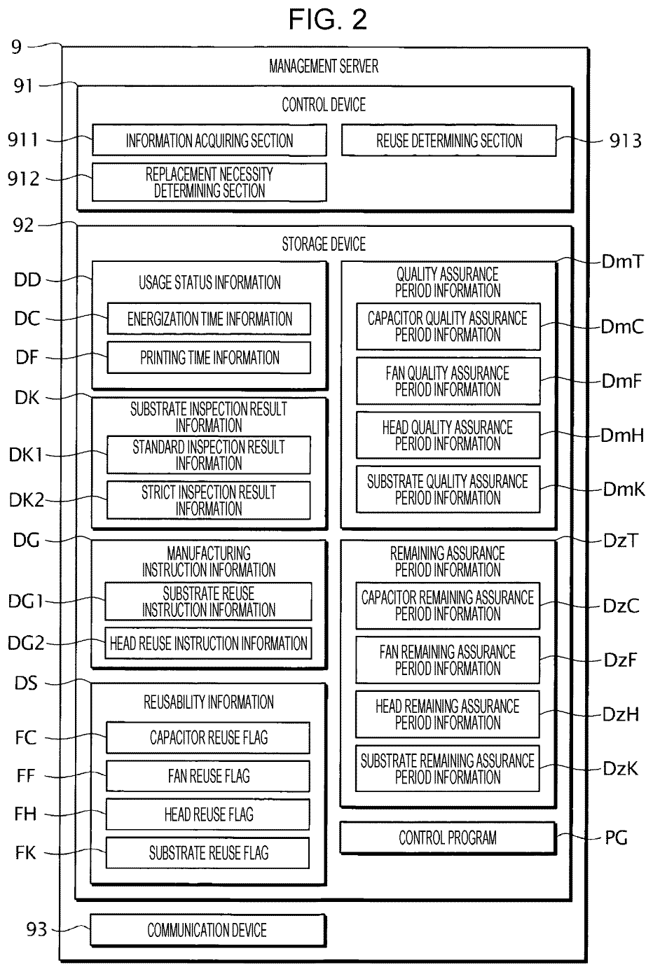

An example of a configuration of the manufacturing management system Sys according to the present embodiment will be described with reference to FIGS. 1 and 2.

FIG. 1 is a block diagram illustrating the example of the configuration of the manufacturing management system Sys.

As illustrated in FIG. 1, the manufacturing management system Sys includes a management server 9, a data acquisition apparatus 81 capable of communicating with the management server 9 via a network NW, an inspection apparatus 82 capable of communicating with the management server 9 via the network NW, and an instruction apparatus 83 capable of communicating with the management server 9 via the network NW, and manages a process of refurbishing a used printing apparatus 1 to manufacture a new printing apparatus 1. The used printing apparatus 1 to be refurbished will be referred to as a used printing apparatus 1x, and the new printing apparatus 1 to be manufactured by refurbishing the used printing apparatus 1x will be referred to as a new printing apparatus 1y.

The data acquisition apparatus 81 acquires usage status information DD from the used printing apparatus 1x. The usage status information DD indicates a usage status of the used printing apparatus 1x.

The inspection apparatus 82 inspects a circuit substrate 500 included in the used printing apparatus 1x, and outputs substrate inspection result information DK indicating a result of the inspection. In the present embodiment, it is assumed that an aluminum electrolytic capacitor Cd and a fan FN are disposed on the circuit substrate 500.

The management server 9 generates manufacturing instruction information DG based on the usage status information DD supplied from the data acquisition apparatus 81 and the substrate inspection result information DK supplied from the inspection apparatus 82, and supplies the generated manufacturing instruction information DG to the instruction apparatus 83. The manufacturing instruction information DG indicates a component that is included in the used printing apparatus 1x and is available for reuse in a case where the used printing apparatus 1x is refurbished to manufacture the new printing apparatus 1y.

Based on the manufacturing instruction information DG, the instruction apparatus 83 presents a screen showing information indicating the component that is available for reuse and included in the used printing apparatus 1x to a worker US who performs work of refurbishing the used printing apparatus 1x to manufacture the new printing apparatus 1y.

A process in which the management server 9 gives, to the worker US, an instruction regarding the manufacturing of the new printing apparatus 1y by generating the manufacturing instruction information DG based on the usage status information DD and the substrate inspection result information DK is hereinafter referred to as a “manufacturing management process”.

FIG. 2 is a block diagram illustrating an example of a configuration of the management server 9.

As illustrated in FIG. 2, the management server 9 includes a control device 91, a storage device 92, and a communication device 93.

The storage device 92 is a storage medium readable by the control device 91. The storage device 92 includes, for example, a volatile memory such as a random-access memory (RAM) that functions as a work area of the control device 91 and a nonvolatile memory such as an electrically erasable programmable read-only memory (EEPROM) that stores various types of information. The storage device 92 stores the usage status information DD, the substrate inspection result information DK, the manufacturing instruction information DG, reusability information DS, quality assurance period information DmT, remaining assurance period information DzT, and a control program PG of the management server 9.

The usage status information DD includes energization time information DC and printing time information DF.

The energization time information DC indicates an energization time TC. The energization time TC is an energization time for the printing apparatus 1. In the present embodiment, it is assumed that a voltage is applied to the aluminum electrolytic capacitor Cd in a period of time when power is supplied to the printing apparatus 1. That is, in the present embodiment, the energization time TC corresponds to the time when the voltage is applied to the aluminum electrolytic capacitor Cd.

The printing time information DF indicates a printing time TF. The printing time TF is the time when the printing apparatus 1 executes a printing process of forming an image on a medium such as a printing sheet. In the present embodiment, it is assumed that the fan FN is operated in a period of time when the printing apparatus 1 executes the printing process. That is, in the present embodiment, the printing time TF corresponds to the operating time of the fan FN. In the present embodiment, a case where the printing time information DF indicates the printing time TF will be described as an example, but the present disclosure is not limited to this aspect. The printing time information DF may indicate the number of times that the printing process is executed, or the printing time information DF may indicate the number of media (printing sheets) on which an image has been formed by the printing process.

The substrate inspection result information DK includes standard inspection result information DK1 and strict inspection result information DK2.

The standard inspection result information DK1 indicates a result of a standard substrate inspection. The standard substrate inspection is an inspection for determining whether the circuit substrate 500 satisfies a standard quality criterion.

The strict inspection result information DK2 indicates a result of a strict substrate inspection. The strict substrate inspection is an inspection for determining whether the circuit substrate 500 satisfies a strict quality criterion that is stricter than the standard quality criterion.

The manufacturing instruction information DG includes substrate reuse instruction information DG1 and head reuse instruction information DG2.

The substrate reuse instruction information DG1 is information for instructing the worker US who manufactures the new printing apparatus 1y whether to reuse the circuit substrate 500 included in the used printing apparatus 1x in a case where the used printing apparatus 1x is refurbished to manufacture the new printing apparatus 1y.

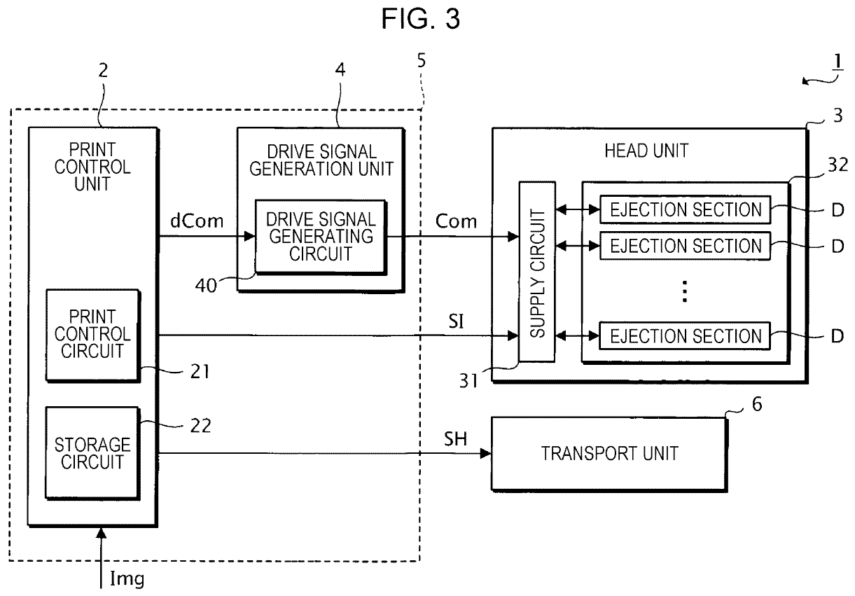

The head reuse instruction information DG2 is information for instructing the worker US who manufactures the new printing apparatus 1y whether to reuse a head unit 3 included in the used printing apparatus 1x in a case where the used printing apparatus 1x is refurbished to manufacture the new printing apparatus 1y. The head unit 3 will be described later with reference to FIG. 3.

The reusability information DS includes a capacitor reuse flag FC, a fan reuse flag FF, a head reuse flag FH, and a substrate reuse flag FK.

The capacitor reuse flag FC indicates whether the aluminum electrolytic capacitor Cd included in the used printing apparatus 1x is available for reuse for manufacturing the new printing apparatus 1y in a case where the used printing apparatus 1x is refurbished to manufacture

### The New Printing Apparatus 1y.

The fan reuse flag FF indicates whether the fan FN included in the used printing apparatus 1x is available for reuse for manufacturing the new printing apparatus 1y in a case where the used printing apparatus 1x is refurbished to manufacture the new printing apparatus 1y.

The head reuse flag FH indicates whether the head unit 3 included in the used printing apparatus 1x is available for reuse for manufacturing the new printing apparatus 1y in a case where the used printing apparatus 1x is refurbished to manufacture the new printing apparatus 1y.

The substrate reuse flag FK indicates whether the circuit substrate 500 included in the used printing apparatus 1x is available for reuse for manufacturing the new printing apparatus 1y in a case where the used printing apparatus 1x is refurbished to manufacture the new printing apparatus 1y.

The quality assurance period information DmT includes capacitor quality assurance period information DmC, fan quality assurance period information DmF, head quality assurance period information DmH, and substrate quality assurance period information DmK.

The capacitor quality assurance period information DmC indicates a quality assurance period of the aluminum electrolytic capacitor Cd in a case where the aluminum electrolytic capacitor Cd included in the printing apparatus 1 is not a used product but a new product. The quality assurance period of the aluminum electrolytic capacitor Cd in a case where the aluminum electrolytic capacitor Cd is a new product is hereinafter referred to as a capacitor quality assurance period TmC.

The fan quality assurance period information DmF indicates a quality assurance period of the fan FN in a case where the fan FN included in the printing apparatus 1 is not a used product but a new product. The quality assurance period of the fan FN in a case where the fan FN is a new product is hereinafter referred to as a fan quality assurance period TmF.

The head quality assurance period information DmH indicates a quality assurance period of the head unit 3 in a case where the head unit 3 included in the printing apparatus 1 is not a used product but a new product. The quality assurance period of the head unit 3 in a case where the head unit 3 is a new product is hereinafter referred to as a head quality assurance period TmH.

The substrate quality assurance period information DmK indicates a quality assurance period of the circuit substrate 500 in a case where the circuit substrate 500 included in the printing apparatus 1 is not a used product but a new product. The quality assurance period of the circuit substrate 500 in a case where the circuit substrate 500 is a new product is hereinafter referred to as a substrate quality assurance period TmK.

The remaining assurance period information DzT includes capacitor remaining assurance period information DzC, fan remaining assurance period information DzF, head remaining assurance period information DzH, and substrate remaining assurance period information DzK.

The capacitor remaining assurance period information DzC indicates a remaining period of the quality assurance period of the used aluminum electrolytic capacitor Cd in a case where the used aluminum electrolytic capacitor Cd included in the used printing apparatus 1x is reused to manufacture the new printing apparatus 1y. The remaining period of the quality assurance period of the used aluminum electrolytic capacitor Cd is referred to as a capacitor remaining assurance period TzC.

The fan remaining assurance period information DzF indicates a remaining period of the quality assurance period of the used fan FN in a case where the used fan FN included in the used printing apparatus 1x is reused to manufacture the new printing apparatus 1y. The remaining period of the quality assurance period of the used fan FN is referred to as a fan remaining assurance period TzF.

The head remaining assurance period information DzH indicates a remaining period of the quality assurance period of the used head unit 3 in a case where the used head unit 3 included in the used printing apparatus 1x is reused to manufacture the new printing apparatus 1y. The remaining period of the quality assurance period of the used head unit 3 is referred to as a head remaining assurance period TzH.

The substrate remaining assurance period information DzK indicates a remaining period of the quality assurance period of the used circuit substrate 500 in a case where the used circuit substrate 500 included in the used printing apparatus 1x is reused to manufacture the new printing apparatus 1y. The remaining period of the quality assurance period of the used circuit substrate 500 is referred to as a substrate remaining assurance period TzK.

The control device 91 includes a processor. The processor included in the control device 91 includes, for example, one or a plurality of central processing units (CPUs). However, the processor included in the control device 91 may include hardware such as a graphics processing unit (GPU), a digital signal processor (DSP), an application specific integrated circuit (ASIC), a programmable logic device (PLD), and a field programmable gate array (FPGA) in addition to the one or plurality of CPUs or instead of some or all of the one or plurality of CPUs. The processor included in the control device 91 can function as an information acquiring section 911, a replacement necessity determining section 912, and a reuse determining section 913 by executing the control program PG stored in the storage device 92 and operating in accordance with the control program PG.

The information acquiring section 911 acquires the usage status information DD including the energization time information DC and the printing time information DF from the used printing apparatus 1x via the data acquisition apparatus 81. The information acquiring section 911 acquires, from the inspection apparatus 82, the result of the inspection of the used printing apparatus 1x, that is, the substrate inspection result information DK including the standard inspection result information DK1 and the strict inspection result information DK2.

In a case where the used printing apparatus 1x is refurbished to manufacture the new printing apparatus 1y, the replacement necessity determining section 912 determines the necessity of replacement of the aluminum electrolytic capacitor Cd disposed on the circuit substrate 500 of the used printing apparatus 1x based on the energization time information DC, determines the necessity of replacement of the fan FN disposed on the circuit substrate 500 of the used printing apparatus 1x based on the printing time information DF, determines the necessity of replacement of the head unit 3 of the used printing apparatus 1x based on the printing time information DF, and determines the necessity of replacement of the circuit substrate 500 of the used printing apparatus 1x based on the standard inspection result information DK1.

Specifically, the replacement necessity determining section 912 determines that the aluminum electrolytic capacitor Cd does not need to be replaced if the energization time TC indicated by the energization time information DC is less than or equal to a threshold TthC. The replacement necessity determining section 912 determines that the aluminum electrolytic capacitor Cd needs to be replaced if the energization time TC is greater than the threshold TthC.

The replacement necessity determining section 912 determines that the fan FN does not need to be replaced if the printing time TF indicated by the printing time information DF is less than or equal to a threshold TthF. The replacement necessity determining section 912 determines that the fan FN needs to be replaced if the printing time TF is greater than the threshold TthF.

The replacement necessity determining section 912 determines that the head unit 3 does not need to be replaced if the printing time TF indicated by the printing time information DF is less than or equal to a threshold TthH. The replacement necessity determining section 912 determines that the head unit 3 needs to be replaced if the printing time TF is greater than the threshold TthH.

The replacement necessity determining section 912 determines that the circuit substrate 500 does not need to be replaced if the standard inspection result information DK1 indicates that the circuit substrate 500 satisfies the standard quality criterion. The replacement necessity determining section 912 determines that the circuit substrate 500 needs to be replaced if the standard inspection result information DK1 indicates that the circuit substrate 500 does not satisfy the standard quality criterion.

When determining that the aluminum electrolytic capacitor Cd does not need to be replaced, the replacement necessity determining section 912 sets the capacitor reuse flag FC to a value “1” indicating that the aluminum electrolytic capacitor Cd does not need to be replaced. When determining that the aluminum electrolytic capacitor Cd needs to be replaced, the replacement necessity determining section 912 sets the capacitor reuse flag FC to a value “0” indicating that the aluminum electrolytic capacitor Cd needs to be replaced.

When determining that the fan FN does not need to be replaced, the replacement necessity determining section 912 sets the fan reuse flag FF to a value “1” indicating that the fan FN does not need to be replaced. When determining that the fan FN needs to be replaced, the replacement necessity determining section 912 sets the fan reuse flag FF to a value “0” indicating that the fan FN needs to be replaced.

When determining that the head unit 3 does not need to be replaced, the replacement necessity determining section 912 sets the head reuse flag FH to a value “1” indicating that the head unit 3 does not need to be replaced. When determining that the head unit 3 needs to be replaced, the replacement necessity determining section 912 sets the head reuse flag FH to a value “0” indicating that the head unit 3 needs to be replaced.

When determining that the circuit substrate 500 does not need to be replaced, the replacement necessity determining section 912 sets the substrate reuse flag FK to a value “1” indicating that the circuit substrate 500 does not need to be replaced. When determining that the circuit substrate 500 needs to be replaced, the replacement necessity determining section 912 sets the substrate reuse flag FK to a value “0” indicating that the circuit substrate 500 needs to be replaced.

In a case where the used printing apparatus 1x is refurbished to manufacture the new printing apparatus 1y, the reuse determining section 913 determines whether to reuse various components included in the used printing apparatus 1x to manufacture the new printing apparatus 1y, based on results of the determination by the replacement necessity determining section 912.

Specifically, in a case where the used printing apparatus 1x is refurbished to manufacture the new printing apparatus 1y, the reuse determining section 913 determines to reuse the aluminum electrolytic capacitor Cd included in the used printing apparatus 1x to manufacture the new printing apparatus 1y on condition that at least the capacitor reuse flag FC indicates the value “1” indicating that the aluminum electrolytic capacitor Cd does not need to be replaced.

In a case where the used printing apparatus 1x is refurbished to manufacture the new printing apparatus 1y, the reuse determining section 913 determines to reuse the fan FN included in the used printing apparatus 1x to manufacture the new printing apparatus 1y on condition that at least the fan reuse flag FF indicates the value “1” indicating that the fan FN does not need to be replaced.

In a case where the used printing apparatus 1x is refurbished to manufacture the new printing apparatus 1y, the reuse determining section 913 determines to reuse the head unit 3 included in the used printing apparatus 1x to manufacture the new printing apparatus 1y on condition that at least the head reuse flag FH indicates the value “1” indicating that the head unit 3 does not need to be replaced.

In a case where the used printing apparatus 1x is refurbished to manufacture the new printing apparatus 1y, the reuse determining section 913 determines to reuse the circuit substrate 500 included in the used printing apparatus 1x to manufacture the new printing apparatus 1y on condition that at least the substrate reuse flag FK indicates the value “1” indicating that the circuit substrate 500 does not need to be replaced.

Then, the reuse determining section 913 generates the manufacturing instruction information DG including the substrate reuse instruction information DG1 and the head reuse instruction information DG2 based on the results of the determination of whether to reuse the various components included in the used printing apparatus 1x to manufacture the new printing apparatus 1y, and supplies the generated manufacturing instruction information DG to the instruction apparatus 83.

The communication device 93 is hardware for communicating with an external device outside the management server 9 via the network NW. In the present embodiment, the information acquiring section 911 acquires the usage status information DD from the data acquisition apparatus 81 via the communication device 93, and acquires the substrate inspection result information DK from the inspection apparatus 82 via the communication device 93. The reuse determining section 913 supplies the manufacturing instruction information DG to the instruction apparatus 83 via the communication device 93.

### A.2. Outline of Printing Apparatus 1

An example of a configuration of the printing apparatus 1 according to the present embodiment will be described with reference to FIG. 3.

FIG. 3 is a functional block diagram illustrating the example of the configuration of the printing apparatus 1.

As illustrated in FIG. 3, image data Img indicating an image to be formed by the printing apparatus 1 is supplied to the printing apparatus 1 from a host computer such as a personal computer or a digital camera. The printing apparatus 1 executes a printing process of forming the image indicated by image data Img supplied from the host computer on a recording sheet PP.

As illustrated in FIG. 3, the printing apparatus 1 includes a print control unit 2 that controls each section of the printing apparatus 1, a head unit 3 including an ejection section D that ejects ink onto the recording sheet PP, a drive signal generation unit 4 including a drive signal generating circuit 40 that generates a drive signal Com for driving the ejection section D, and a transport unit 6 that transports the head unit 3 and the recording sheet PP. A unit including the print control unit 2 and the drive signal generation unit 4 is referred to as a “drive control unit 5”.

In the present embodiment, it is assumed that the printing apparatus 1 includes one head unit 3 and one drive signal generation unit 4. However, the present disclosure is not limited to this aspect. The printing apparatus 1 may include a plurality of head units 3 and a plurality of drive signal generation units 4 corresponding one-to-one to the plurality of head units 3.

The print control unit 2 includes a print control circuit 21 and a storage circuit 22.

The storage circuit 22 includes a volatile memory such as a RAM and a nonvolatile memory such as a ROM, an EEPROM, or a PROM, and stores various types of information such as a control program of the printing apparatus 1. The storage circuit 22 stores the energization time information DC indicating the energization time TC and the printing time information DF indicating the printing time TF.

The print control circuit 21 includes one or a plurality of CPUs. However, the print control circuit 21 may include a programmable logic device such as an FPGA instead of the one or plurality of CPUs or in addition to the one or plurality of CPUs. The print control circuit 21 executes the control program of the printing apparatus 1 stored in the storage circuit 22, and operates in accordance with the control program to control each section of the printing apparatus 1. Specifically, the print control circuit 21 generates signals for controlling the operation of each section of the printing apparatus 1, such as a specifying signal SI, a waveform specifying signal dCom, and a transport control signal SH. The print control circuit 21 updates the energization time TC indicated by the energization time information DC according to a period of time when a power source of the printing apparatus 1 is on. The print control circuit 21 updates the printing time TF indicated by the printing time information DF according to a period of time when the printing apparatus 1 executes the printing process.

The waveform specifying signal dCom is a digital signal for defining a waveform of the drive signal Com. The drive signal Com is an analog signal for driving the ejection section D. The specifying signal SI is a digital signal specifying the type of operation of the ejection section D. Specifically, the specifying signal SI specifies whether the drive signal Com is supplied to the ejection section D, and thus specifies the type of operation of the ejection section D, such as specifying whether to eject ink from the ejection section D. The transport control signal SH is a signal for controlling the transport unit 6.

When the printing process is executed, the print control unit 2 generates a signal for controlling the head unit 3, such as the specifying signal SI, based on the image data Img. When the printing process is executed, the print control unit 2 generates a signal for controlling the drive signal generation unit 4, such as the waveform specifying signal dCom. When the printing process is executed, the print control unit 2 generates a signal for controlling the transport unit 6, such as the transport control signal SH. Therefore, in the printing process, the print control unit 2 controls each section of the printing apparatus 1 to form the image corresponding to the image data Img on the recording sheet PP by adjusting whether ink is ejected from the ejection unit D, the timing of ejecting the ink, and the like while controlling the transport unit 6 to move the head unit 3 and the recording sheet PP.

The head unit 3 includes a supply circuit 31 and a head section 32.

The head section 32 includes M ejection sections D. In this case, the value M is a natural number that satisfies “M≥1”.

The supply circuit 31 switches whether to supply the drive signal Com to the ejection section D, based on the specifying signal SI.

The drive control unit 5 includes the circuit substrate 500. In the present embodiment, the print control circuit 21 and the storage circuit 22 included in the print control unit 2, and the drive signal generating circuit 40 included in the drive signal generation unit 4 are disposed on the circuit substrate 500.

### A.3. Configuration of Drive Signal Generating Circuit 40

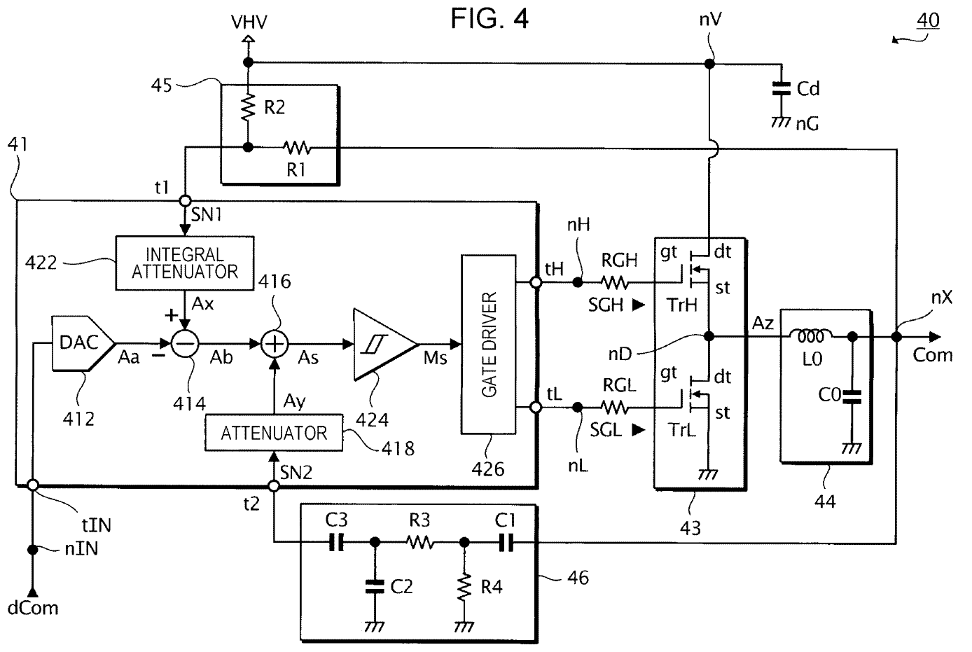

An example of a configuration of the drive signal generating circuit 40 included in the drive signal generation unit 4 will be described below with reference to FIG. 4.

FIG. 4 is a block diagram illustrating an example of a circuit configuration of the drive signal generating circuit 40.

As illustrated in FIG. 4, the drive signal generating circuit 40 is a class-D amplification circuit that includes an integrated circuit 41, an amplifier circuit 43, a smoothing circuit 44, a pull-up circuit 45, a filter circuit 46, and the aluminum electrolytic capacitor Cd, and generates the drive signal Com based on the waveform specifying signal dCom.

The integrated circuit 41 is, for example, a large scale integration (LSI) circuit, and generates a gate signal SGH and a gate signal SGL based on the waveform specifying signal dCom supplied to a terminal tIN through a node nIN. The integrated circuit 41 includes an analog conversion circuit 412, a subtractor 414, an adder 416, an attenuator 418, an integral attenuator 422, a comparator 424, and a gate driver 426.

The analog conversion circuit 412 is a digital-to-analog converter (DAC) and converts the digital waveform specifying signal dCom into an analog signal Aa. The voltage amplitude of the signal Aa is, for example, about 0 volts to 2 volts, and a signal obtained by amplifying the voltage of the signal Aa by about 20 times is the drive signal Com. That is, the signal Aa is a signal before the amplification of the drive signal Com.

The integral attenuator 422 outputs a signal Ax obtained by attenuating and integrating a signal SN1 input to a terminal t1 to be described below.

The subtractor 414 outputs a signal Ab indicating an electrical potential obtained by subtracting the electrical potential of the signal Aa from the electrical potential of the signal Ax.

The attenuator 418 outputs a signal Ay obtained by attenuating a high-frequency component of a signal SN2 input to a terminal t2 to be described below.

The adder 416 outputs a signal As indicating an electrical potential obtained by adding the electrical potential of the signal Ab to the electrical potential of the signal Ay.

The comparator 424 outputs a modulated signal Ms obtained by pulse-modulating the signal As. Specifically, the comparator 424 outputs the modulated signal Ms that becomes a high level when the voltage of the signal As increases and becomes greater than or equal to a threshold voltage Vth1, and that becomes a low level when the voltage of the signal As decreases and becomes less than a threshold voltage Vth2. The threshold voltage Vth1 and the threshold voltage Vth2 are set to have a relationship of “Vth1>Vth2”.

Note that a power supply voltage of a circuit from the analog conversion circuit 412 to the comparator 424 is a low voltage such as 3.3 volts. Meanwhile, the drive signal Com has a large amplitude, and may exceed 40 volts, for example. Therefore, the integral attenuator 422 attenuates the signal SN1 having an amplitude corresponding to the drive signal Com, and matches an amplitude range of the signal Ax with an amplitude range of a signal in the circuit from the analog conversion circuit 412 to the comparator 424.

In the present embodiment, the digital signal is described as the waveform specifying signal dCom as an example, but the waveform specifying signal dCom may be any signal that defines a target value for generating the drive signal Com, and for example, the analog signal Aa may be used as the waveform specifying signal dCom. In a case where the signal Aa is the waveform specifying signal dCom, the integrated circuit 41 may be configured without the analog conversion circuit 412.

The gate driver 426 outputs the gate signal SGH, which is obtained by converting the modulated signal Ms into a signal having a specific amplitude, to a node nH through a terminal tH. The gate driver 426 outputs the gate signal SGL, which is obtained by converting a signal obtained by inverting the logic level of the modulated signal Ms into a specific amplitude, to a node nL through a terminal tL.

The amplifier circuit 43 includes, for example, a transistor TrH and a transistor TrL, and generates an amplified signal Az obtained by amplifying the modulated signal Ms, based on the gate signal SGH and the gate signal SGL output from the integrated circuit 41. In the present embodiment, as an example, it is assumed that the transistor TrH and the transistor TrL are field-effect transistors. More specifically, in the present embodiment, it is assumed that N-channel type metal-oxide-semiconductor field-effect transistors (MOSFETs) are used as the transistor TrH and the transistor TrL.

The gate signal SGH output from the gate driver 426 to the terminal tH is input to a gate electrode gt of the transistor TrH through the node nH and a resistor RGH. The gate signal SGL output from the gate driver 426 to the terminal tL is input to a gate electrode gt of the transistor TrL through the node nL and a resistor RGL. Logic levels of the gate signal SGH and the gate signal SGL are mutually exclusive. In this case, “being mutually exclusive” means that the signal level of the gate signal SGH supplied to the gate electrode gt of the transistor TrH and the signal level of the gate signal SGL supplied to the gate electrode gt of the transistor TrL are not a high level at the same time, in other words, the transistor TrH and the transistor TrL are not on at the same time. The transistor TrH is on when the electrical potential of the gate electrode gt of the transistor TrH is at a high level, and is off when the electrical potential of the gate electrode gt of the transistor TrH is at a low level. The transistor TrL is on when the electrical potential of the gate electrode gt of the transistor TrL is at a high level, and is off when the electrical potential of the gate electrode gt of the transistor TrL is at a low level.

A drain electrode dt of the transistor TrH is electrically coupled to a node nV set to a power supply electrical potential VHV on the high electrical potential side, and a source electrode st of the transistor TrH is electrically coupled to a node nD. A source electrode st of the transistor TrL is electrically coupled to a node nG set to a ground electrical potential, and a drain electrode dt of the transistor TrL is electrically coupled to the node nD. The source electrode of the transistor TrL may be electrically coupled to a power supply line LD set to an electrical potential VBS.

As described above, the transistor TrH is on when the gate signal SGH supplied to the gate electrode gt of the transistor TrH is at a high level, and is off when the gate signal SGH supplied to the gate electrode gt of the transistor TrH is at a low level. The transistor TrL is on when the gate signal SGL supplied to the gate electrode gt of the transistor TrL is at a high level, and is off when the gate signal SGL supplied to the gate electrode gt of the transistor TrL is at a low level. Therefore, the amplified signal Az obtained by amplifying the modulated signal Ms is output to the node nD electrically coupling the source electrode st of the transistor TrH and the drain electrode dt of the transistor TrL.

The aluminum electrolytic capacitor Cd is coupled to the node nV to which the power supply electrical potential VHV is supplied. One end of the aluminum electrolytic capacitor Cd is electrically coupled to the node nV, and the other end of the aluminum electrolytic capacitor Cd is electrically coupled to the node nG set to the ground electrical potential. In the present embodiment, the electrolytic capacitor Cd is, for example, a large-capacity aluminum electrolytic capacitor, and suppresses a fluctuation in the electrical potential at the node nV to stabilize the power supply electrical potential VHV.

The smoothing circuit 44 is a low pass filter (LPF), and smooths the amplified signal Az to generate the drive signal Com. The smoothing circuit 44 includes an inductor L0 and a capacitor C0. One end of the inductor L0 is electrically coupled to the node nD, and the other end of the inductor L0 is electrically coupled to a node nX. One end of the capacitor C0 is electrically coupled to the node nX, and the other end of the capacitor C0 is electrically coupled to the node nG set to the ground electrical potential.

The pull-up circuit 45 feeds back the signal SN1, which is obtained by pulling up the drive signal Com output to the node nX, to the terminal t1. The pull-up circuit 45 includes a resistor R1 having one end electrically coupled to the node nX and the other end electrically coupled to the terminal t1, and a resistor R2 having one end electrically coupled to the terminal t1 and the other end electrically coupled to the node nV set to the power supply electrical potential VHV.

The filter circuit 46 is a band pass filter (BPF), and feeds back, to the terminal t2, the signal SN2 obtained by removing a direct-current component from a frequency component included in the drive signal Com and having a frequency in a predetermined band. The filter circuit 46 includes a resistor R3, a capacitor C1, a resistor R4, a capacitor C2, and a capacitor C3. The capacitor C1 has one end electrically coupled to the node nX, and the other end electrically coupled to one end of the resistor R3. The resistor R4 has one end electrically coupled to the one end of the resistor R3, and the other end electrically coupled to the node nG set to the ground electrical potential. The capacitor C2 has one end electrically coupled to the other end of the resistor R3, and the other end electrically coupled to the node nG set to the ground electrical potential. The capacitor C3 has one end electrically coupled to the other end of the resistor R3, and the other end electrically coupled to the terminal t2. Among these, the capacitor C1 and the resistor R4 function as a high pass filter (HPF) that passes a high-frequency component included in the drive signal Com and having a frequency higher than or equal to a cutoff frequency of the HPF. The resistor R3 and the capacitor C2 function as a low pass filter (LPF) that passes a low-frequency component included in the drive signal Com and having a frequency lower than or equal to a cutoff frequency of the LPF. In the present embodiment, in the filter circuit 46, the cutoff frequency of the HPF is set to be lower than the cutoff frequency of the LPF. Therefore, the filter circuit 46 passes a frequency component included in the drive signal Com and having a frequency that is in the predetermined band and higher than or equal to the cutoff frequency of the HPF and lower than or equal to the cutoff frequency of the LPF. In addition, since the filter circuit 46 includes the capacitor C3, the filter circuit 46 feeds back, to the terminal t2, a signal obtained by removing a direct-current component from a signal included in the drive signal Com, having passed through the HPF and the LPF, and having a frequency component in the predetermined band.

In this way, the drive signal generating circuit 40 generates the drive signal Com by smoothing the amplified signal Az at the node nD by the smoothing circuit 44. The drive signal Com is integrated and attenuated by the integral attenuator 422, and then fed back to the subtractor 414. Therefore, the drive signal generating circuit 40 self-oscillates at a frequency determined by a delay in the smoothing circuit 44, a delay in the integral attenuator 422, and a transfer function for the feedback. However, since the amount of a delay in a feedback path extending through the terminal t1 is large, it is not possible to increase the frequency of the self-oscillation only by the feedback through the terminal t1 to the extent that the accuracy of the waveform of the drive signal Com can be sufficiently secured. On the other hand, in the present embodiment, since a path for feeding back a high-frequency component of the drive signal Com through the terminal t2 is disposed separately from the path extending through the terminal t1, it is possible to reduce a delay in the feedback in the entire drive signal generating circuit 40. That is, in the present embodiment, the frequency of the signal As obtained by adding the signal Ay, which is the high-frequency component of the drive signal Com, to the signal Ab can be increased, as compared to a case where the path extending through the terminal t2 is not present, and thus it is possible to sufficiently secure the accuracy of the drive signal Com.

### A.4. Configuration of Drive Control Unit 5

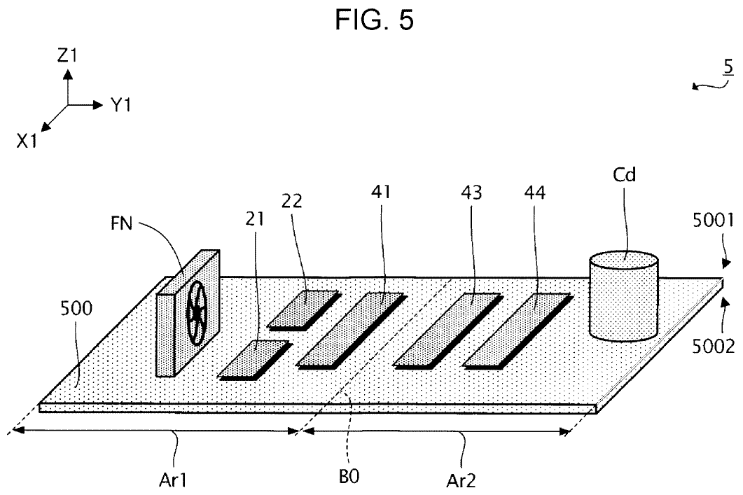

A configuration of the drive control unit 5 will be described below with reference to FIGS. 5 to 9.

FIG. 5 is a perspective view illustrating an example of the configuration of the drive control unit 5.

As illustrated in FIG. 5, the drive control unit 5 includes the circuit substrate 500, and the print control unit 2, the drive signal generation unit 4, and the fan FN that are disposed on the circuit substrate 500. More specifically, the circuit substrate 500 has an upper surface 5001 and a lower surface 5002, and the drive control unit 5 includes the circuit substrate 500, and the print control circuit 21, the storage circuit 22, the integrated circuit 41, the amplifier circuit 43, the smoothing circuit 44, the aluminum electrolytic capacitor Cd, and the fan FN that are disposed on the upper surface 5001. FIG. 5 does not illustrate some electronic components of the drive signal generating circuit 40.

In the present embodiment, a case where the circuit substrate 500 extends on a plane extending in an X1 direction and a Y1 direction and having a normal direction that is a Z1 direction is assumed as an example. In this case, the Y1 direction is orthogonal to the X1 direction, and the Z1 direction is orthogonal to the X1 direction and the Y1 direction. Hereinafter, the X1 direction and an X2 direction opposite to the X1 direction are referred to as an X-axis direction, the Y1 direction and a Y2 direction opposite to the Y1 direction are referred to as a Y-axis direction, and the Z1 direction and a Z2 direction opposite to the Z1 direction are referred to as a Z-axis direction. In the present embodiment, as an example, it is assumed that the X-axis direction, the Y-axis direction, and the Z-axis direction are orthogonal to each other. However, the present disclosure is not limited to this aspect. The X-axis direction, the Y-axis direction, and the Z-axis direction may intersect each other.

In the present embodiment, it is assumed that the upper surface 5001 faces the Z1 direction, and the lower surface 5002 faces the Z2 direction and is opposite to the upper surface 5001.

As illustrated in FIG. 5, the circuit substrate 500 is divided into a digital drive region Ar1 and an analog drive region Ar2.

The digital drive region Ar1 is a region in which a digital signal flows in wiring and an electronic component that are disposed in the digital drive region Ar1. In the present embodiment, it is assumed that the print control circuit 21, the storage circuit 22, the integrated circuit 41, and the fan FN are disposed in the digital drive region Ar1.

The analog drive region Ar2 is a region in which an analog signal flows in wiring and an electronic circuit that are disposed in the analog drive region Ar2. In the present embodiment, it is assumed that the amplifier circuit 43, the smoothing circuit 44, and the aluminum electrolytic capacitor Cd are disposed in the analog drive region Ar2.

In the present embodiment, an aspect in which the fan FN is disposed in the digital drive region Ar1 will be described as an example, but the present disclosure is not limited to this aspect. The fan FN may be disposed in the analog drive region Ar2.

In the present embodiment, a case where a boundary B0 between the digital drive region Ar1 and the analog drive region Ar2 is a straight line is exemplified, but the boundary B0 has any shape.

As described above, in the present embodiment, digital signals such as the waveform specifying signal dCom and the specifying signal SI that flow in the printing apparatus 1 have a small amplitude of about 3.3 volts. On the other hand, an analog signal such as the drive signal Com that flows in the printing apparatus 1 has a large amplitude of about 40 volts. Therefore, in the present embodiment, a higher voltage is applied to the analog drive region Ar2 than to the digital drive region Ar1.

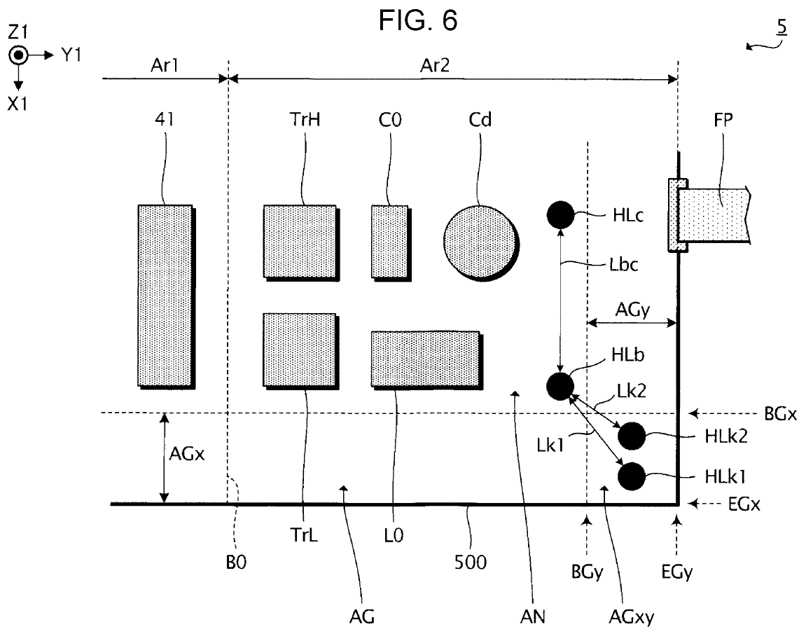

FIG. 6 is a plan view illustrating an example of the configuration of the drive control unit 5. Specifically, FIG. 6 is a plan view illustrating the example of the configuration of the drive control unit 5 when the circuit substrate 500 is viewed from the Z1 direction to the Z2 direction.

As illustrated in FIG. 6, the circuit substrate 500 is divided into an outer peripheral region AG and an inner region AN.

The outer peripheral region AG is present between an outer periphery EG of the circuit substrate 500 and a virtual boundary line BG provided at a predetermined interval from the outer periphery EG. Specifically, the outer peripheral region AG includes an outer peripheral region AGy between an outer periphery EGy defining an end portion of the circuit substrate 500 in the Y1 direction and a virtual boundary line BGy provided at a predetermined interval from the outer periphery EGy, and an outer peripheral region AGx between an outer periphery EGx defining an end portion of the circuit substrate 500 in the X1 direction and a virtual boundary line BGx provided at a predetermined interval from the outer periphery EGx.

In the present embodiment, a flexible printed circuit substrate FP is disposed in the outer peripheral region AGy. The flexible printed circuit substrate FP is a substrate on which wiring for supplying the drive signal Com from the circuit substrate 500 to the head unit 3 is disposed.

A region where the outer peripheral region AGx and the outer peripheral region AGy overlap each other is hereinafter referred to as an end portion region AGxy. The end portion region AGxy includes an intersection of the outer periphery EGx and the outer periphery EGy, that is, a corner of the circuit substrate 500.

The inner region AN is located at an interval greater than or equal to a predetermined interval from the outer periphery EG. In the present embodiment, it is assumed that various electronic components such as the integrated circuit 41, the amplifier circuit 43, and the smoothing circuit 44 are disposed in the inner region AN.

As illustrated in FIG. 6, the circuit substrate 500 has a signal through-hole HLc, a reference through-hole HLb, a standard inspection through-hole HLk1, and a strict inspection through-hole HLk2.

The signal through-hole HLc includes a through-hole penetrating the circuit substrate 500 in the Z-axis direction and wiring inserted into the through-hole. The drive signal Com is supplied to the signal through-hole HLc. In the present embodiment, the signal through-hole HLc is disposed in the inner region AN. However, the signal through-hole HLc may be disposed in the outer peripheral region AG.

The reference through-hole HLb includes a through-hole penetrating the circuit substrate 500 in the Z-axis direction and wiring inserted into the through-hole. The reference through-hole HLb is set to the ground electrical potential. In the present embodiment, the reference through-hole HLb is disposed in the inner region AN. However, the reference through-hole HLb may be disposed in the outer peripheral region AG.

The standard inspection through-hole HLk1 includes a through-hole penetrating the circuit substrate 500 in the Z-axis direction, and wiring inserted into the through-hole. When the printing apparatus 1 is used, for example, when the printing process is executed, a signal is not supplied to the standard inspection through-hole HLk1, and for example, the standard inspection through-hole HLk1 is in a floating state in which the standard inspection through-hole HLk1 is electrically independent of other conductors. At the time of the inspection of the circuit substrate 500 by the inspection apparatus 82, an inspection signal is supplied to the standard inspection through-hole HLk1. In this case, the inspection signal has an electrical potential different from the ground electrical potential.

In the present embodiment, the standard inspection through-hole HLk1 is disposed in the end portion region AGxy. However, the present disclosure is not limited to this aspect. The standard inspection through-hole HLk1 may be disposed in the outer peripheral region AG other than the end portion region AGxy, or may be disposed in the inner region AN.

In the present embodiment, the standard inspection through-hole HLk1 is disposed in the analog drive region Ar2. However, the present disclosure is not limited to this aspect. The standard inspection through-hole HLk1 may be disposed in the digital drive region Ar1.

In the present embodiment, a distance LK1 between the standard inspection through-hole HLk1 and the reference through-hole HLb is shorter than a distance Lbc between the signal through-hole HLc and the reference through-hole HLb.

The strict inspection through-hole HLk2 includes a through-hole penetrating the circuit substrate 500 in the Z-axis direction and wiring inserted into the through-hole. When the printing apparatus 1 is used, for example, when the printing process is executed, a signal is not supplied to the strict inspection through-hole HLk2, and is, for example, in a floating state. At the time of the inspection of the circuit substrate 500 by the inspection apparatus 82, the inspection signal is supplied to the strict inspection through-hole HLk2.

In the present embodiment, the strict inspection through-hole HLk2 is disposed in the end portion region AGxy. However, the present disclosure is not limited to this aspect. The strict inspection through-hole HLk2 may be disposed in the outer peripheral region AG other than the end portion region AGxy, or may be disposed in the inner region AN.

In the present embodiment, the strict inspection through-hole HLk2 is disposed in the analog drive region Ar2. However, the present disclosure is not limited to this aspect. The strict inspection through-hole HLk2 may be disposed in the digital drive region Ar1.

Further, in the present embodiment, a distance LK2 between the strict inspection through-hole HLk2 and the reference through-hole HLb is shorter than the distance LK1 between the standard inspection through-hole HLk1 and the reference through-hole HLb.

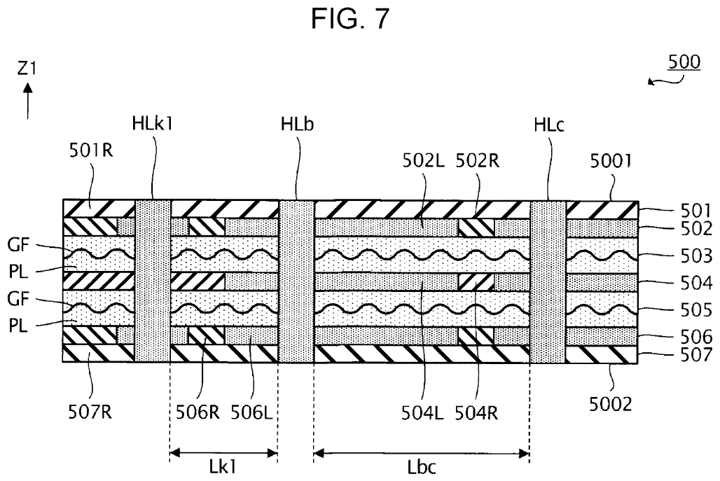

FIG. 7 is a cross-sectional view illustrating an example of a configuration of the circuit substrate 500. Specifically, FIG. 7 is a cross-sectional view of the circuit substrate 500 taken in the Z1 direction so as to include a polygonal line extending through the signal through-hole HLc, the reference through-hole HLb, and the standard inspection through-hole HLk1 when the circuit substrate 500 is viewed in the Z1 direction.

As illustrated in FIG. 7, the circuit substrate 500 is a multilayer substrate including a plurality of layers including a surface layer 501, a wiring layer 502, an insulating layer 503, a wiring layer 504, an insulating layer 505, a wiring layer 506, and a surface layer 507 that are disposed between the upper surface 5001 and the lower surface 5002.

The surface layer 501 includes the upper surface 5001, and includes wiring 501L (not illustrated) and a resist 501R. The wiring 501L is made of a conductive material such as copper or aluminum, for example. The resist 501R is made of, for example, an insulating resin such as an epoxy resin.

The wiring layer 502 is disposed between the surface layer 501 and the lower surface 5002, and includes wiring 502L and an insulating portion 502R. The wiring 502L is made of a conductive material such as copper or aluminum, for example. The insulating portion 502R is made of, for example, an insulating resin such as an epoxy resin.

The insulating layer 503 is disposed between the wiring layer 502 and the lower surface 5002, and includes a glass fiber GF and an insulating resin PL. The glass fiber GF is fibrous glass disposed so as to extend along a plane having a normal direction that is the Z-axis direction. The insulating resin PL is an insulating resin such as an epoxy resin.

The wiring layer 504 is disposed between the insulating layer 503 and the lower surface 5002, and includes wiring 504L and an insulating portion 504R. The wiring 504L is made of a conductive material such as copper or aluminum, for example. The insulating portion 504R is made of, for example, an insulating resin such as an epoxy resin.

The insulating layer 505 is disposed between the wiring layer 504 and the lower surface 5002, and includes a glass fiber GF and an insulating resin PL.

The wiring layer 506 is disposed between the insulating layer 505 and the lower surface 5002, and includes wiring 506L and an insulating portion 506R. The wiring 506L is made of a conductive material such as copper or aluminum, for example. The insulating portion 506R is made of, for example, an insulating resin such as an epoxy resin.

The surface layer 507 includes the lower surface 5002, and includes wiring 507L (not illustrated) and a resist 507R. The wiring 507L is made of a conductive material such as copper or aluminum, for example. The resist 507R is made of, for example, an insulating resin such as an epoxy resin.

As illustrated in FIG. 7, the signal through-hole HLc, the reference through-hole HLb, the standard inspection through-hole HLk1, and the strict inspection through-hole HLk2 are disposed so as to penetrate the circuit substrate 500 in the Z-axis direction (the strict inspection through-hole HLk2 is not illustrated in FIG. 7).

Incidentally, one of causes of the degradation of the circuit substrate 500 is a so-called dendrite in which an ion precipitated from metal contained in the circuit substrate 500 progresses into a resin form. In particular, in a case where a substrate including a glass fiber GF is used as in the circuit substrate 500, a dendrite grows along the glass fiber GF. Then, when the dendrite grows, two conductors provided apart from each other, for example, two through-holes are electrically coupled by the dendrite, and a short circuit occurs.

In general, as a voltage applied to the dendrite increases, the growth rate of the dendrite also increases. Therefore, a dendrite grows more easily in the analog drive region Ar2 than in the digital drive region Ar1.

In addition, as the humidity of an environment in which a dendrite is present increases, the growth rate of the dendrite also increases. Therefore, a dendrite grows at a high rate in the printing apparatus 1 including the head unit 3 that ejects ink. In particular, the growth rate of a dendrite is higher in the outer peripheral region AG which is easily affected by ink mist floating in the printing apparatus 1 than in the inner region AN which is not easily affected by the ink mist.

If a voltage applied to each portion of the circuit substrate 500 is uniform and the humidity in each portion of the circuit substrate 500 is also uniform, dendrites may occur with a uniform probability in the entire circuit substrate 500. If the voltage applied to each portion of the circuit substrate 500 is uniform and the humidity in each portion of the circuit substrate 500 is also uniform, the degrees of growth of the dendrites are also substantially the same in the entire circuit substrate 500.

Therefore, by inspecting whether a short circuit has occurred between the standard inspection through-hole HLk1 and the reference through-hole HLb and whether a short circuit has occurred between the strict inspection through-hole HLk2 and the reference through-hole HLb, it is possible to estimate the degree of growth of a dendrite between the signal through-hole HLc and the reference through-hole HLb.

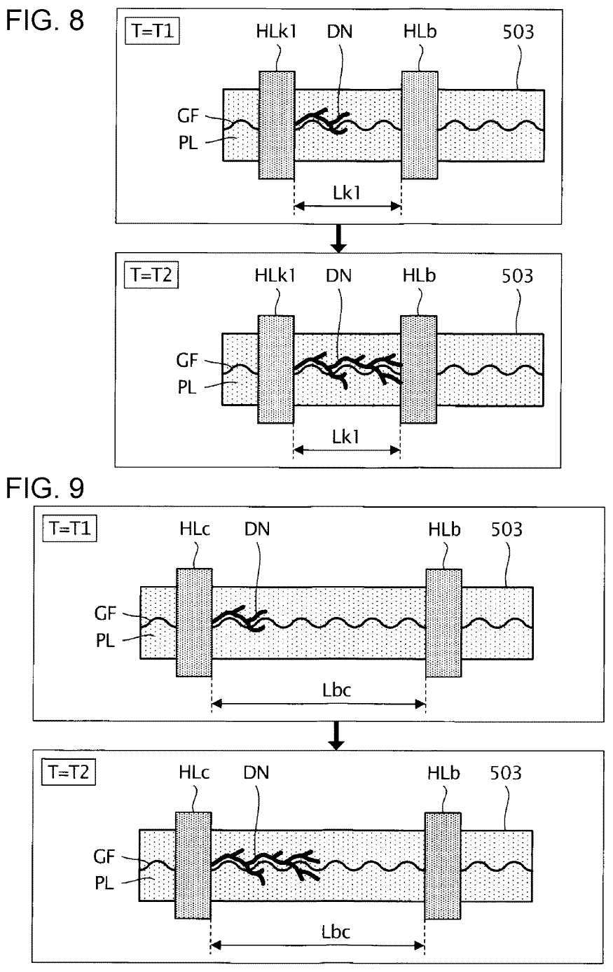

FIG. 8 is a schematic diagram illustrating the degree of growth of a dendrite between the standard inspection through-hole HLk1 and the reference through-hole HLb. FIG. 9 is a schematic view illustrating the degree of growth of a dendrite between the signal through-hole HLc and the reference through-hole HLb.

As illustrated in FIG. 8, at time T1 after the shipment of the printing apparatus 1, a dendrite DN is in a state of growing from the standard inspection through-hole HLk1 toward the reference through-hole HLb. However, at time T1, the length of the dendrite DN is shorter than the distance LK1, and the standard inspection through-hole HLk1 and the reference through-hole HLb are maintained in an insulated state. In the present embodiment, the inspection apparatus 82 inspects whether a current flows between the standard inspection through-hole HLk1 and the reference through-hole HLb by applying a voltage between the standard inspection through-hole HLk1 and the reference through-hole HLb. In addition, the inspection apparatus 82 inspects whether a current flows between the strict inspection through-hole HLk2 and the reference through-hole HLb by applying a voltage between the strict inspection through-hole HLk2 and the reference through-hole HLb. In the example illustrated in FIG. 8, at time T1, even when the inspection apparatus 82 applies the voltage between the standard inspection through-hole HLk1 and the reference through-hole HLb, a current does not flow between the standard inspection through-hole HLk1 and the reference through-hole HLb.

Thereafter, at time T2, the length of the dendrite DN is longer than or equal to the distance LK1, and the standard inspection through-hole HLk1 and the reference through-hole HLb are short-circuited. Therefore, at time T2, when the inspection apparatus 82 applies a voltage between the standard inspection through-hole HLk1 and the reference through-hole HLb, a current flows between the standard inspection through-hole HLk1 and the reference through-hole HLb.

As illustrated in FIG. 9, at time T1, the dendrite DN grows from the signal through-hole HLc toward the reference through-hole HLb. However, at time T1, the length of the dendrite DN is shorter than the distance LK1. Since the distance Lbc is longer than the distance LK1, the length of the dendrite DN is shorter than the distance Lbc at time T1. Therefore, at time T1, when a current does not flow between the standard inspection through-hole HLk1 and the reference through-hole HLb even when the inspection apparatus 82 applies a voltage between the standard inspection through-hole HLk1 and the reference through-hole HLb, it is estimated that the signal through-hole HLc and the reference through-hole HLb are also in an insulated state.

Thereafter, at time T2, when the length of the dendrite DN is longer than or equal to the distance LK1, and the standard inspection through-hole HLk1 and the reference through-hole HLb are short-circuited, it is highly likely that the length of the dendrite DN is also shorter than the distance Lbc because the distance Lbc is longer than the distance LK1. However, the growth rate of the dendrite DN includes a stochastic element. Therefore, at time T2, when the standard inspection through-hole HLk1 and the reference through-hole HLb are short-circuited, there is a possibility that the length of the dendrite DN may be longer than or equal to the distance Lbc. Therefore, in the present embodiment, at time T2, when the inspection apparatus 82 applies a voltage between the standard inspection through-hole HLk1 and the reference through-hole HLb, and a current flows between the standard inspection through-hole HLk1 and the reference through-hole HLb, the inspection apparatus 82 regards the signal through-hole HLc and the reference through-hole HLb as being short-circuited.

The distance LK2 is shorter than the distance LK1. Therefore, in the present embodiment, at time T2, when the inspection apparatus 82 applies the voltage between the standard inspection through-hole HLk1 and the reference through-hole HLb and a current does not flow between the standard inspection through-hole HLk1 and the reference through-hole HLb even when the inspection apparatus 82 applies a voltage between the strict inspection through-hole HLk2 and the reference through-hole HLb and a current flows between the strict inspection through-hole HLk2 and the reference through-hole HLb, the inspection apparatus 82 regards the signal through-hole HLc and the reference through-hole HLb as being in an insulated state.

### A.5. Manufacturing Management Process

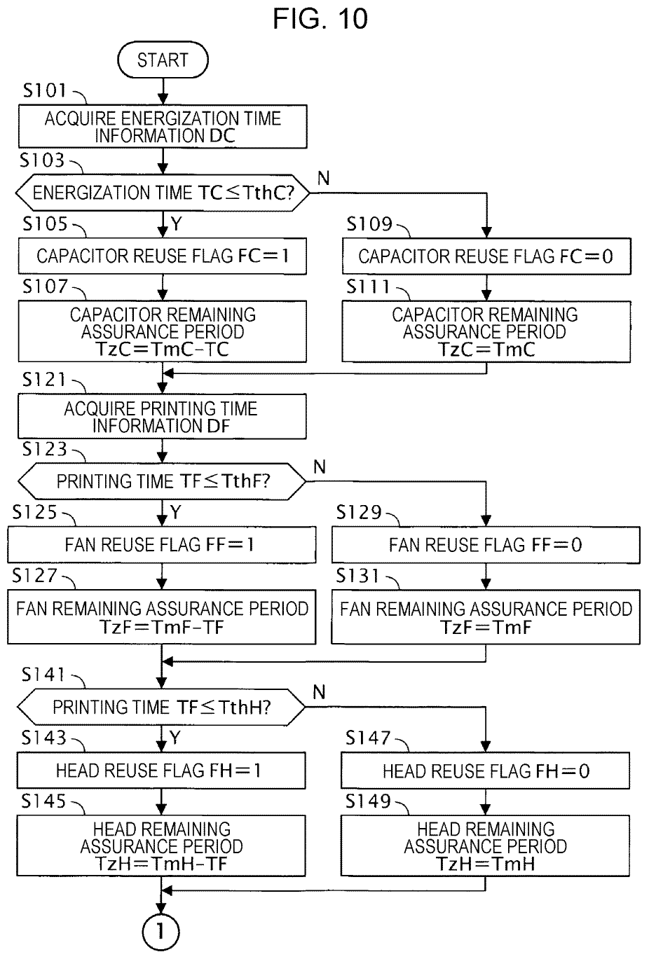

Hereinafter, an operation of the management server 9 when the manufacturing management process is executed will be described with reference to FIGS. 10 to 13.

FIGS. 10 to 13 are flowcharts illustrating an example of the operation of the management server 9 when the management server 9 executes the manufacturing management process. The manufacturing management process in the flowcharts illustrated in FIGS. 10 to 13 is executed for refurbishing the used printing apparatus 1x to manufacture the new printing apparatus 1y.

As illustrated in FIG. 10, when the manufacturing management process is started and the data acquisition apparatus 81 acquires the energization time information DC from the used printing apparatus 1x, the information acquiring section 911 acquires the energization time information DC from the data acquisition apparatus 81 (S101). In step S101, the information acquiring section 911 may directly acquire the energization time information DC from the used printing apparatus 1x.

Next, the replacement necessity determining section 912 determines whether the energization time TC indicated by the energization time information DC is less than or equal to the threshold TthC (S103).

If the result of the determination in step S103 is positive, the replacement necessity determining section 912 determines that the aluminum electrolytic capacitor Cd does not need to be replaced, and sets the capacitor reuse flag FC to the value “1” indicating that the aluminum electrolytic capacitor Cd does not need to be replaced (S105).

Then, the reuse determining section 913 subtracts the energization time TC indicated by the energization time information DC acquired in step S101 from the capacitor quality assurance period TmC indicated by the capacitor quality assurance period information DmC to calculate the capacitor remaining assurance period TzC (S107), stores the capacitor remaining assurance period information DzC indicating the calculated capacitor remaining assurance period TzC into the storage device 92, and then advances the process to step S121.

If the result of the determination in step S103 is negative, the replacement necessity determining section 912 determines that the aluminum electrolytic capacitor Cd needs to be replaced, and sets the capacitor reuse flag FC to the value “0” indicating that the aluminum electrolytic capacitor Cd needs to be replaced (S109).

Thereafter, the reuse determining section 913 sets the capacitor quality assurance period TmC indicated by the capacitor quality assurance period information DmC as the capacitor remaining assurance period TzC (S111), stores the capacitor remaining assurance period information DzC indicating the capacitor remaining assurance period TzC into the storage device 92, and then advances the process to step S121.

Thereafter, the information acquiring section 911 acquires the printing time information DF from the data acquisition apparatus 81 (S121). In step S121, the information acquiring section 911 may directly acquire the printing time information DF from the used printing apparatus 1x.

Next, the replacement necessity determining section 912 determines whether the printing time TF indicated by the printing time information DF is less than or equal to the threshold TthF (S123).

If the result of the determination in step S123 is positive, the replacement necessity determining section 912 determines that the fan FN does not need to be replaced, and sets the fan reuse flag FF to the value “1” indicating that the fan FN does not need to be replaced (S125).

Then, the reuse determining section 913 calculates the fan remaining assurance period TzF by subtracting the printing time TF indicated by the printing time information DF acquired in step S121 from the fan quality assurance period TmF indicated by the fan quality assurance period information DmF (S127), stores the fan remaining assurance period information DzF indicating the calculated fan remaining assurance period TzF into the storage device 92, and advances the process to step S141.

If the result of the determination in step S123 is negative, the replacement necessity determining section 912 determines that the fan FN needs to be replaced, and sets the fan reuse flag FF to the value “0” indicating that the fan FN needs to be replaced (S129).

Then, the reuse determining section 913 sets the fan quality assurance period TmF indicated by the fan quality assurance period information DmF as the fan remaining assurance period TzF (S131), stores the fan remaining assurance period information DzF indicating the fan remaining assurance period TzF into the storage device 92, and advances the process to step S141.

Thereafter, the replacement necessity determining section 912 determines whether the printing time TF indicated by the printing time information DF is less than or equal to the threshold TthH (S141).

If the result of the determination in step S141 is positive, the replacement necessity determining section 912 determines that the head unit 3 does not need to be replaced, and sets the head reuse flag FH to the value “1” indicating that the head unit 3 does not need to be replaced (S143).

Then, the reuse determining section 913 calculates the head remaining assurance period TzH by subtracting the printing time TF indicated by the printing time information DF acquired in step S121 from the head quality assurance period TmH indicated by the head quality assurance period information DmH (S145), stores the head remaining assurance period information DzH indicating the calculated head remaining assurance period TzH into the storage device 92, and advances the process to step S151.

If the result of the determination in step S141 is negative, the replacement necessity determining section 912 determines that the head unit 3 needs to be replaced, and sets the head reuse flag FH to the value “0” indicating that the head unit 3 needs to be replaced (S147).

Then, the reuse determining section 913 sets the head quality assurance period TmH indicated by the head quality assurance period information DmH as the head remaining assurance period TzH (S149), stores the head remaining assurance period information DzH indicating the head remaining assurance period TzH into the storage device 92, and advances the process to step S151.

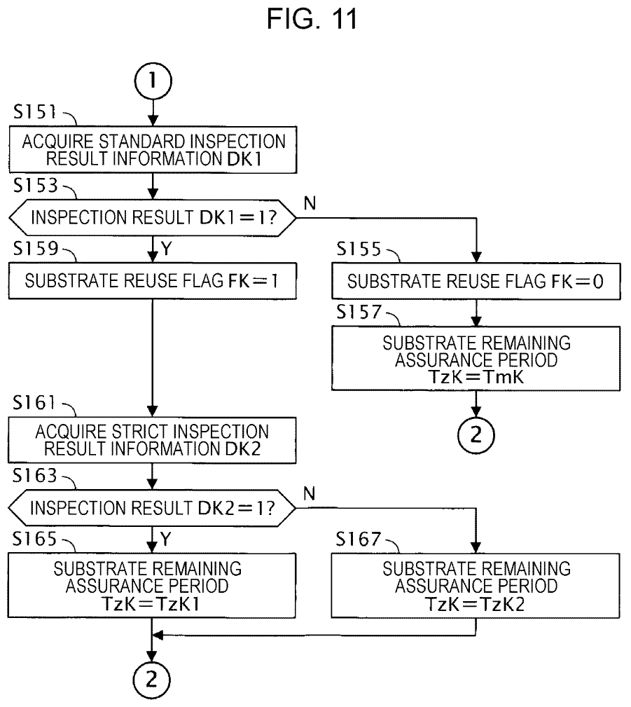

As illustrated in FIG. 11, the information acquiring section 911 acquires the standard inspection result information DK1 from the inspection apparatus 82 (S151).

Next, the replacement necessity determining section 912 determines whether a value indicated by the standard inspection result information DK1 is a value “1” indicating that the circuit substrate 500 satisfies the standard quality criterion (S153).

When the inspection apparatus 82 applies a voltage between the standard inspection through-hole HLk1 and the reference through-hole HLb of the circuit substrate 500 of the used printing apparatus 1x as the standard substrate inspection, no current flows between the standard inspection through-hole HLk1 and the reference through-hole HLb, and the inspection apparatus 82 regards the standard inspection through-hole HLk1 and the reference through-hole HLb as being in an insulated state, the inspection apparatus 82 sets, in the standard inspection result information DK1, the value “1” indicating that the circuit substrate 500 satisfies the standard quality criterion.

Meanwhile, when the inspection apparatus 82 applies a voltage between the standard inspection through-hole HLk1 and the reference through-hole HLb of the circuit substrate 500 of the used printing apparatus 1x as the standard substrate inspection, a current flows between the standard inspection through-hole HLk1 and the reference through-hole HLb and there is a possibility that the standard inspection through-hole HLk1 and the reference through-hole HLb may be short-circuited, the inspection apparatus 82 sets, in the standard inspection result information DK1, a value “0” indicating that the circuit substrate 500 does not satisfy the standard quality criterion.

If the result of the determination in step S153 is negative, the replacement necessity determining section 912 determines that the circuit substrate 500 needs to be replaced, and sets the substrate reuse flag FK to the value “0” indicating that the circuit substrate 500 needs to be replaced (S155).

Then, the reuse determining section 913 sets the substrate quality assurance period TmK indicated by the substrate quality assurance period information DmK as the substrate remaining assurance period TzK (S157), stores the substrate remaining assurance period information DzK indicating the substrate remaining assurance period TzK into the storage device 92, and then advances the process to step S171.

If the result of the determination in step S153 is positive, the replacement necessity determining section 912 determines that the circuit substrate 500 does not need to be replaced, and sets the substrate reuse flag FK to the value “1” indicating that the circuit substrate 500 does not need to be replaced (S159).

Next, the information acquiring section 911 acquires the strict inspection result information DK2 from the inspection apparatus 82 (S161).

Then, the replacement necessity determining section 912 determines whether a value indicated by the strict inspection result information DK2 is a value “1” indicating that the circuit substrate 500 satisfies the strict quality criterion (S163).

When the inspection apparatus 82 applies a voltage between the strict inspection through-hole HLk2 and the reference through-hole HLb of the circuit substrate 500 of the used printing apparatus 1x as the strict substrate inspection, no current flows between the strict inspection through-hole HLk2 and the reference through-hole HLb, and the inspection apparatus 82 regards the strict inspection through-hole HLk2 and the reference through-hole HLb as being in an insulated state, the inspection apparatus 82 sets, in the strict inspection result information DK2, the value “1” indicating that the circuit substrate 500 satisfies the strict quality criterion.

Meanwhile, when the inspection apparatus 82 applies a voltage between the strict inspection through-hole HLk2 and the reference through-hole HLb of the circuit substrate 500 included in the used printing apparatus 1x as the strict substrate inspection, a current flows between the strict inspection through-hole HLk2 and the reference through-hole HLb, and there is a possibility that the strict inspection through-hole HLk2 and the reference through-hole HLb may be short-circuited, the inspection apparatus 82 sets, in the strict inspection result information DK2, a value “0” indicating that the circuit substrate 500 does not satisfy the strict quality criterion.

If the result of the determination in step S163 is positive, the reuse determining section 913 sets the substrate remaining assurance period TzK indicated by the substrate remaining assurance period information DzK to a period TzK1 (S165), and advances the process to step S171.

If the result of the determination in step S163 is negative, the reuse determining section 913 sets the substrate remaining assurance period TzK indicated by the substrate remaining assurance period information DzK to a period TzK2 (S167), and advances the process to step S171.

In this case, the period TzK1 and the period TzK2 satisfy “TmK>TzK122 TzK2>0”. That is, the period TzK1 is shorter than the substrate quality assurance period TmK and longer than the period TzK2. The period TzK2 is shorter than the period TzK1 and longer than “0”.

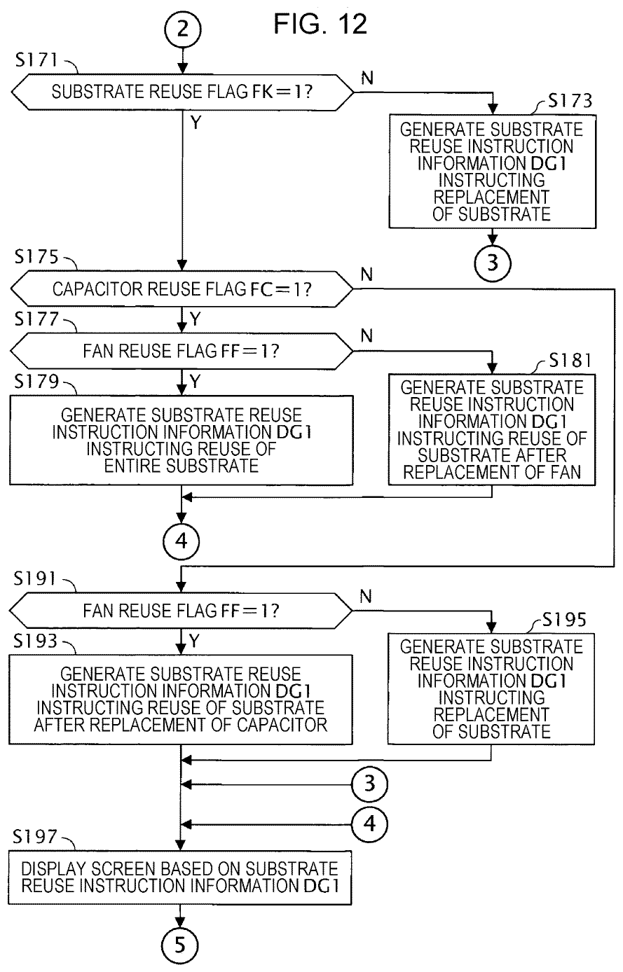

As illustrated in FIG. 12, the reuse determining section 913 determines whether the substrate reuse flag FK indicates the value “1” indicating that the circuit substrate 500 does not need to be replaced (S171).

If the result of the determination in step S171 is negative, the reuse determining section 913 generates substrate reuse instruction information DG1 for instructing replacement of the circuit substrate 500 (S173), and advances the process to step S197.

If the result of the determination in step S171 is positive, the reuse determining section 913 determines whether the capacitor reuse flag FC indicates the value “1” indicating that the aluminum electrolytic capacitor Cd does not need to be replaced (S175).

If the result of the determination in step S175 is positive, the reuse determining section 913 determines whether the fan reuse flag FF indicates the value “1” indicating that the fan FN does not need to be replaced (S177).

If the result of the determination in step S177 is positive, the reuse determining section 913 generates substrate reuse instruction information DG1 for instructing reuse of the circuit substrate 500, the aluminum electrolytic capacitor Cd, and the fan FN (S179), and advances the process to step S197.

If the result of the determination in step S177 is negative, the reuse determining section 913 replaces the fan FN, generates substrate reuse instruction information DG1 for instructing reuse of the circuit substrate 500 and the aluminum electrolytic capacitor Cd (S181), and advances the process to step S197.

If the result of the determination in step S175 is negative, the reuse determining section 913 determines whether the fan reuse flag FF indicates the value “1” indicating that the fan FN does not need to be replaced (S191).

If the result of the determination in step S191 is positive, the reuse determining section 913 replaces the aluminum electrolytic capacitor Cd, generates substrate reuse instruction information DG1 for instructing reuse of the circuit substrate 500 and the fan FN (S193), and advances the process to step S197.

If the result of the determination in step S191 is negative, the reuse determining section 913 generates substrate reuse instruction information DG1 for instructing replacement of the circuit substrate 500 (S195), and advances the process to step S197.

Thereafter, the reuse determining section 913 supplies the substrate reuse instruction information DG1 to the instruction apparatus 83, causes the instruction apparatus 83 to display a screen showing the substrate reuse instruction information DG1 (S197), and advances the process to step S201.

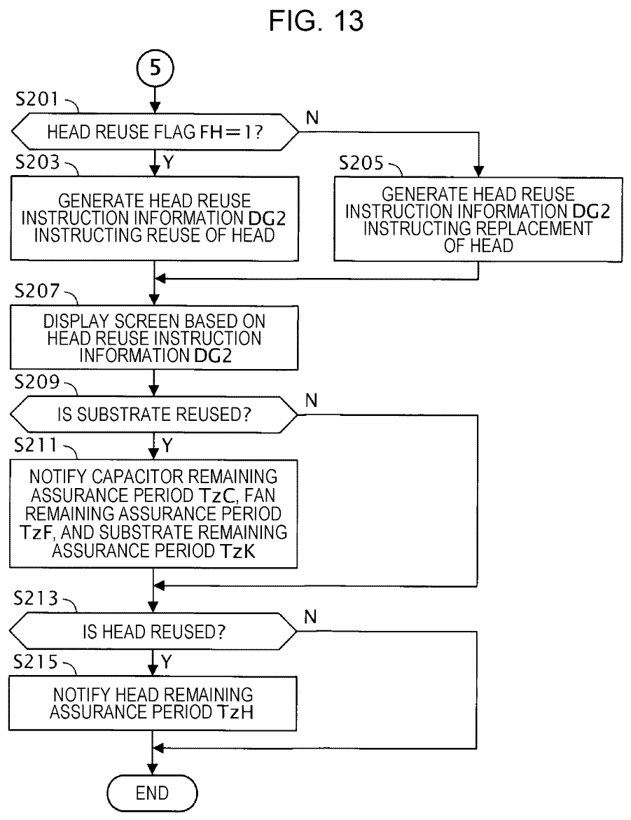

As illustrated in FIG. 13, the reuse determining section 913 determines whether the head reuse flag FH indicates the value “1” indicating that the head unit 3 does not need to be replaced (S201).

If the result of the determination in step S201 is positive, the reuse determining section 913 generates head reuse instruction information DG2 instructing reuse of the head unit 3 (S203), and advances the process to step S207.

If the result of the determination in step S201 is negative, the reuse determining section 913 generates head reuse instruction information DG2 instructing replacement of the head unit 3 (S205), and advances the process to step S207.

Thereafter, the reuse determining section 913 supplies the head reuse instruction information DG2 to the instruction apparatus 83, and causes the instruction apparatus 83 to display a screen showing the head reuse instruction information DG2 (S207).

In a case where the used printing apparatus 1x is refurbished to manufacture the new printing apparatus 1y, the reuse determining section 913 determines whether to reuse the circuit substrate 500 (S209).

If the result of the determination in step S209 is positive, the reuse determining section 913 notifies, via the instruction apparatus 83, the new printing apparatus 1y of the capacitor remaining assurance period information DzC indicating the capacitor remaining assurance period TzC, the fan remaining assurance period information DzF indicating the fan remaining assurance period TzF, and the substrate remaining assurance period information DzK indicating the substrate remaining assurance period TzK (S211). In step S211, the reuse determining section 913 may directly supply the capacitor remaining assurance period information DzC, the fan remaining assurance period information DzF, and the substrate remaining assurance period information DzK to the new printing apparatus 1y.

If the result of the determination in step S209 is negative, the reuse determining section 913 advances the process to step S213.

In addition, in a case where the used printing apparatus 1x is refurbished to manufacture the new printing apparatus 1y, the reuse determining section 913 determines whether to reuse the head unit 3 (S213).

If the result of the determination in step S213 is positive, the reuse determining section 913 notifies the new printing apparatus 1y of the head remaining assurance period information DzH indicating the head remaining assurance period TzH via the instruction apparatus 83 (S215), and ends the manufacturing management process illustrated in the flowcharts of FIGS. 10 to 13. In step S215, the reuse determining section 913 may directly supply the head remaining assurance period information DzH to the new printing apparatus 1y.

If the result of the determination in step S213 is negative, the reuse determining section 913 ends the manufacturing management process illustrated in the flowcharts of FIGS. 10 to 13.

### A.6. Summary of First Embodiment

As described above, according to the present embodiment, a suitability for reuse is determined using the individual determination criteria corresponding to each of the aluminum electrolytic capacitor Cd, the fan FN, the circuit substrate 500, and the head unit 3. Therefore, according to the present embodiment, it is possible to accurately determine a suitability for reuse of each component, as compared to an aspect in which a common determination criterion is used to determine a suitability for reuse of a plurality of components.

In addition, according to the present embodiment, the manufacturing management system Sys determines whether the circuit substrate 500 is available for reuse, based on the standard inspection result information DK1 which is the result of the standard substrate inspection for the used printing apparatus 1x, in addition to the energization time information DC and the printing time information DF acquired from the used printing apparatus 1x. Therefore, according to the present embodiment, it is possible to accurately determine the degree of degradation of the circuit substrate 500 and to accurately determine a suitability for reuse of the circuit substrate 500, as compared to an aspect in which the standard substrate inspection is not performed.

Further, according to the present embodiment, the manufacturing management system Sys performs the strict substrate inspection on the used printing apparatus 1x in addition to the standard substrate inspection. Therefore, according to the present embodiment, it is possible to accurately determine the degree of degradation of the circuit substrate 500 in multiple stages and to accurately estimate the remaining assurance period of the circuit substrate 500 in multiple stages, as compared to an aspect in which the strict substrate inspection is not performed.

### B. MODIFICATIONS

Each embodiment described above can be modified in various manners. Specific modifications will be described below. Two or more aspects selected in any manner from the following examples can be appropriately combined with one another within a range in which the aspects are not inconsistent with one another. In the modifications described below, elements having the same effects and functions as those described in the embodiments will be given the reference signs used in the above description, and each detailed description thereof will be appropriately omitted.

### First Modification

In the above-described embodiments, the aspect in which the aluminum electrolytic capacitor Cd or the fan FN disposed on the circuit substrate 500 is replaced as necessary in a case where the used printing apparatus 1x is refurbished to manufacture the new printing apparatus 1y has been described as an example, but the present disclosure is not limited to this aspect. In a case where the used printing apparatus 1x is refurbished to manufacture the new printing apparatus 1y, the circuit substrate 500 may be reused or replaced on a substrate basis, and each of the various components, such as the aluminum electrolytic capacitor Cd or the fan FN disposed on the circuit substrate 500, may not be replaced on a component basis.

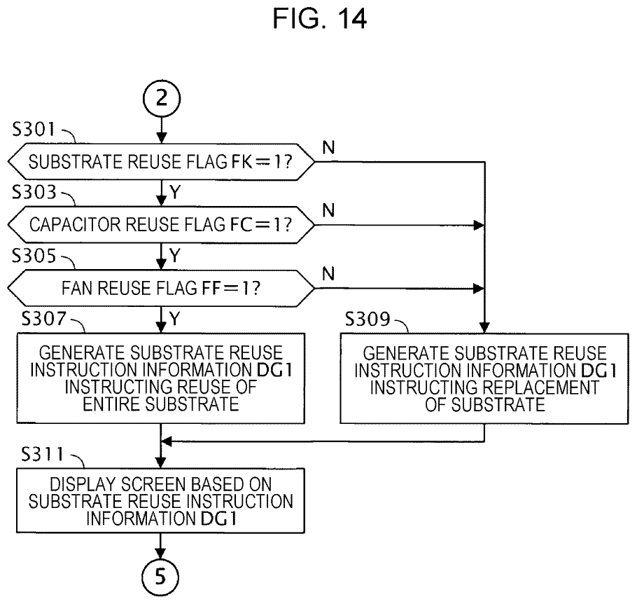

FIG. 14 is a flowchart illustrating an example of an operation of the management server 9 when the management server 9 executes a manufacturing management process according to the present modification. The manufacturing management process according to the present modification is different from the manufacturing management process according to the embodiment in that processing in steps S303 to S311 illustrated in FIG. 14 is performed instead of the processing in steps S171 to S197 illustrated in FIG. 12 in the flowcharts illustrated in FIGS. 10 to 13. Therefore, in the present modification, detailed description of the processing in steps S101 to S167 illustrated in FIGS. 10 and 11 and the processing in steps S201 to S215 illustrated in FIG. 13 will be omitted.

As illustrated in FIG. 14, in the management server 9, after the manufacturing management process is started and the processing in steps S101 to S167 illustrated in FIGS. 10 and 11 is executed, the reuse determining section 913 determines whether the substrate reuse flag FK indicates the value “1” indicating that the circuit substrate 500 does not need to be replaced (S301).

If the result of the determination in step S301 is positive, the reuse determining section 913 determines whether the capacitor reuse flag FC indicates the value “1” indicating that the aluminum electrolytic capacitor Cd does not need to be replaced (S303).

If the result of the determination in step S303 is positive, the reuse determining section 913 determines

whether the fan reuse flag FF indicates the value “1” indicating that the fan FN does not need to be replaced (S305).

If the result of the determination in step S305 is positive, the reuse determining section 913 generates substrate reuse instruction information DG1 for instructing reuse of the circuit substrate 500, the aluminum electrolytic capacitor Cd, and the fan FN (S307), and advances the process to step S311.

If the result of the determination in step S301 is negative, or if the result of the determination in step S303 is negative, or if the result of the determination in step S305 is negative, the reuse determining section 913 generates substrate reuse instruction information DG1 for instructing replacement of the circuit substrate 500 (S309), and advances the process to step S311.

Thereafter, the reuse determining section 913 supplies the substrate reuse instruction information DG1 to the instruction apparatus 83, causes the instruction apparatus 83 to display a screen showing the substrate reuse instruction information DG1 (S311), and advances the process to step S201 illustrated in FIG. 13.

As described above, according to the present modification, in a case where the used printing apparatus 1x is refurbished to manufacture the new printing apparatus 1y, the circuit substrate 500 is reused or replaced on a substrate basis, and each of the various components is not replaced on a component basis. Therefore, it is possible to reduce time and effort required for manufacturing the new printing apparatus 1y, as compared to an aspect in which replacement work is performed on various components disposed on the circuit substrate 500 on a component basis.

### Second Modification

In the above-described embodiments and the first modification, the printing apparatus 1 has been described as an example of an electronic apparatus to be refurbished. However, the present disclosure is not limited to this aspect. The electronic apparatus to be refurbished may be any electronic apparatus other than the printing apparatus 1, such as a smartphone, a digital camera, or a projector.

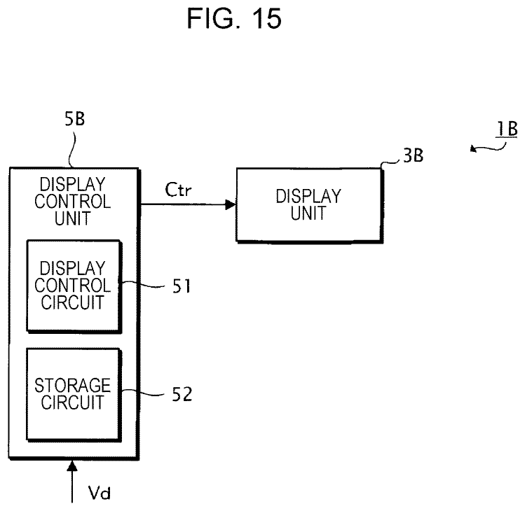

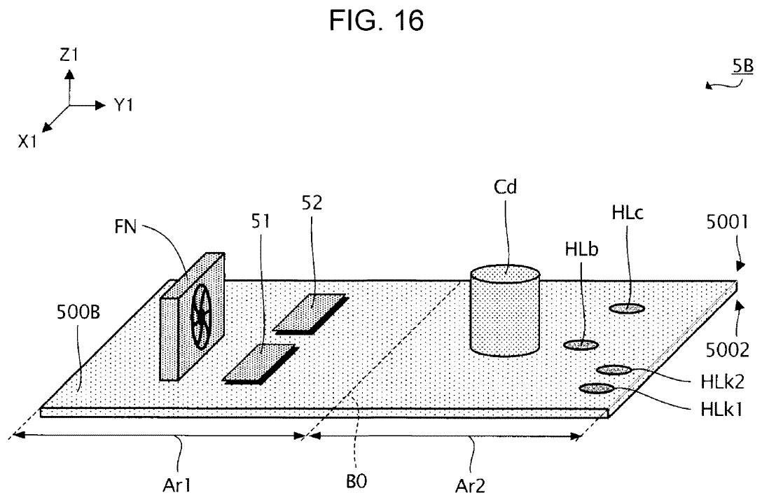

FIG. 15 is a functional block diagram illustrating an example of a configuration of a projector 1B.

As illustrated in FIG. 15, video data Vd indicating a video to be projected by the projector 1B is supplied to the projector 1B from a host computer such as a personal computer or a digital camera. The projector 1B projects the video indicated by the video data Vd supplied from the host computer to the outside using a display unit 3B.

As illustrated in FIG. 15, the projector 1B includes a display control unit 5B that generates a display control signal Ctr based on the video data Vd, and the display unit 3B that projects the video indicated by the video data Vd based on the display control signal Ctr.

The display control unit 5B includes a display control circuit 51 that generates the display control signal Ctr based on the video data Vd, and a storage circuit 52 that stores various types of information such as a control program of the projector 1B.

The storage circuit 52 stores display time information DB and energization time information DC. The energization time information DC indicates an energization time TC for the projector 1B. The display time information DB indicates a display time TB that is the time when the display unit 3B projects a video.

A circuit including the display control circuit 51 and the storage circuit 52 is hereinafter referred to as a drive control circuit 50B.

FIG. 16 is a perspective view illustrating an example of a configuration of the display control unit 5B.

As illustrated in FIG. 16, the display control unit 5B includes a circuit substrate 500B, and a display control circuit 51, a storage circuit 52, an aluminum electrolytic capacitor Cd, and a fan FN that are disposed on the circuit substrate 500B.

In the present modification, the display control circuit 51, the storage circuit 52, and the fan FN are disposed in a digital drive region Ar1, and the aluminum electrolytic capacitor Cd is disposed in an analog drive region Ar2.

A signal through-hole HLc, a reference through-hole HLb, a standard inspection through-hole HLk1, and a strict inspection through-hole HLk2 are disposed in the circuit substrate 500B, similarly to the circuit substrate 500.

In the present modification, the manufacturing management system Sys includes the management server 9, the data acquisition apparatus 81, the inspection apparatus 82, and the instruction apparatus 83, as in the embodiments.

The data acquisition apparatus 81 acquires the energization time information DC and the display time information DB from the projector 1B.

The inspection apparatus 82 inspects the circuit substrate 500B included in the projector 1B, and outputs standard inspection result information DK1 and strict inspection result information DK2 that indicate results of the inspection.

The management server 9 executes a manufacturing management process of generating substrate reuse instruction information DG1 and display unit reuse instruction information DG3 based on the energization time information DC, the display time information DB, the standard inspection result information DK1, and the strict inspection result information DK2. In this case, the display unit reuse instruction information DG3 is information for instructing a worker US who manufactures the new projector 1B whether to reuse the display unit 3B included in the used projector 1B in a case where the used projector 1B is refurbished to manufacture a new projector 1B. The manufacturing management process according to the present modification is the same as the manufacturing management process according to the embodiment, except that the display time information DB is used instead of the printing time information DF and that the display unit reuse instruction information DG3 is generated instead of the head reuse instruction information DG2.

Based on the substrate reuse instruction information DG1 and the display unit reuse instruction information DG3, the instruction apparatus 83 presents a screen showing information indicating a component available for reuse and included in the used projector 1B to the worker US who performs work of refurbishing the used projector 1B to manufacture the new projector 1B.

As described above, according to the present modification, a suitability for reuse is determined using the individual determination criteria corresponding to each of the aluminum electrolytic capacitor Cd, the fan FN, the circuit substrate 500B, and the display unit 3B. Therefore, according to the present modification, it is possible to accurately determine a suitability for reuse of each component, as compared to an aspect in which a common determination criterion is used to determine a suitability for reuse of a plurality of components.

In addition, according to the present modification, the manufacturing management system Sys determines whether the circuit substrate 500B is available for reuse, based on the standard inspection result information DK1 that is a result of the standard substrate inspection for the used projector 1B, in addition to the energization time information DC and the display time information DB acquired from the used projector 1B. Therefore, according to the present modification, it is possible to accurately determine the degree of degradation of the circuit substrate 500B and to accurately determine a suitability for reuse of the circuit substrate 500B, as compared with an aspect in which the standard substrate inspection is not performed.

In addition, according to the modification example, the manufacturing management system Sys performs the strict substrate inspection on the used projector 1B, in addition to the standard substrate inspection. Therefore, according to the present modification, it is possible to accurately determine the degree of degradation of the circuit substrate 500B and to accurately estimate the remaining assurance period of the circuit substrate 500B, as compared to an aspect in which the strict substrate inspection is not performed.

### Third Modification

In the above-described embodiments and the first modification, the aspect in which the drive control unit 5 is disposed separately from the head unit 3 has been described as an example, but the present disclosure is not limited to this aspect. A portion or all of the drive control unit 5 may be mounted on the head unit 3.

### C. SUPPLEMENTARY NOTES

Aspects related to the above description are appended below. In order to facilitate understanding of each of the aspects, in the following description, reference signs in the drawings are given in parentheses for convenience, but it is not intended that the present disclosure is limited to the aspects illustrated in the drawings.

### C.1. Supplementary Note 1

A manufacturing management system Sys according to Supplementary Note 1 will be described below. Hereinafter, a circuit substrate 500 included in a used printing apparatus 1x may be referred to as a used circuit substrate 500x, an aluminum electrolytic capacitor Cd included in the used printing apparatus 1x may be referred to as a used aluminum electrolytic capacitor Cdx, a fan FN included in the used printing apparatus 1x may be referred to as a used fan FNx, a drive control unit 5 included in the used printing apparatus 1x may be referred to as a used drive control unit 5x, and a head unit 3 included in the used printing apparatus 1x may be referred to as a used head unit 3x. In addition, hereinafter, a circuit substrate 500 included in a new printing apparatus 1y may be referred to as a new circuit substrate 500y, an aluminum electrolytic capacitor Cd included in the new printing apparatus 1y may be referred to as a new aluminum electrolytic capacitor Cdy, a fan FN included in the new printing apparatus 1y may be referred to as a new fan FNy, a drive control unit 5 included in the new printing apparatus 1y may be referred to as a new drive control unit 5y, and a head unit 3 included in the new printing apparatus 1y may be referred to as a new head unit 3y.

### Supplementary Note 1-1

There is provided a manufacturing management system Sys according to Supplementary Note 1-1 for a new printing apparatus 1y, wherein the new printing apparatus 1y includes a new drive control unit 5y including a new circuit substrate 500y, a new aluminum electrolytic capacitor Cdy disposed on the new circuit substrate 500y, and a new fan FNy disposed on the new circuit substrate 500y, and a new head unit 3y that is controlled by the new drive control unit 5y, and a used electronic apparatus 1x includes a used drive control unit 5x that includes a used circuit substrate 500x, a used aluminum electrolytic capacitor Cdx disposed on the used circuit substrate 500x and having a same function as the new aluminum electrolytic capacitor Cdy, and a used fan FNx disposed on the used circuit substrate 500x and having a same function as the new fan FNy, and has a same function as the new drive control unit 5y, and a used head unit 3x that is controlled by the used drive control unit 5x and has a same function as the new head unit 3y, the manufacturing management system Sys including: an information acquiring section 911 that acquires, from the used printing apparatus 1x, energization time information DC indicating an energization time TC for the used printing apparatus 1x, and printing time information DF indicating a printing time TF of the used head unit 3x; a replacement necessity determining section 912 that determines necessity of replacement of the used aluminum electrolytic capacitor Cdx by using a threshold TthC for the energization time TC for the used printing apparatus 1x, and the energization time information DC, and determines necessity of replacement of the used fan FNx by using a threshold TthF for the printing time TF of the used printing apparatus 1x, and the printing time information DF; and a reuse determining section 913 that determines to manufacture the new printing apparatus 1y in which a quality assurance period of the new printing apparatus 1y is set to be shorter than a quality assurance period of the used printing apparatus 1x at time of shipment of the used printing apparatus 1x, by using the used drive control unit 5x included in the used printing apparatus 1x as the new drive control unit 5y, if the replacement necessity determining section 912 determines that the used aluminum electrolytic capacitor Cdx does not need to be replaced and that the used fan FNx does not need to be replaced, that determines to manufacture the new printing apparatus 1y without using the used drive control unit 5x included in the used printing apparatus 1x, if the replacement necessity determining section 912 determines that the used aluminum electrolytic capacitor Cdx needs to be replaced and that the used fan FNx does not need to be replaced, and that determines to manufacture the new printing apparatus 1y without using the used drive control unit 5x included in the used printing apparatus 1x, if the replacement necessity determining section 912 determines that the used aluminum electrolytic capacitor Cdx does not need to be replaced and that the used fan FNx needs to be replaced.

In Supplementary Note 1, the new printing apparatus 1y is an example of an “electronic apparatus”, the new circuit substrate 500y is an example of a “first circuit substrate”, the new aluminum electrolytic capacitor Cdy is an example of a “first component”, the new fan FNy is an example of a “second component”, the new drive control unit 5y is an example of a “first control unit”, the new head unit 3y is an example of a “first drive unit”, the used printing apparatus 1x is an example of “another electronic apparatus”, the used circuit substrate 500x is an example of a “second circuit substrate”, the used aluminum electrolytic capacitor Cdx is an example of a “third component”, the used fan FNx is an example of a “fourth component”, the used drive control unit 5x is an example of a “second control unit”, the used head unit 3x is an example of a “second drive unit”, the information acquiring section 911 is an example of an “acquiring section”, the replacement necessity determining section 912 is an example of a “first determining section”, the reuse determining section 913 is an example of a “second determining section”, the energization time information DC is an example of “first information”, the printing time information DF is an example of “second information”, the threshold TthC is an example of a “first criterion”, and the threshold TthF is an example of a “second criterion”.

According to Supplementary Note 1-1, a suitability for reuse is determined using the thresholds TthC and TthF which are individual determination criteria corresponding to the used aluminum electrolytic capacitor Cdx and the used fan FNx, respectively. Therefore, according to Supplementary Note 1-1, it is possible to accurately determine a suitability for reuse of each component, compared to an aspect in which a common determination criterion is used to determine a suitability for reuse of a plurality of components.

### Supplementary Note 1-2

There is provided a manufacturing management system Sys according to Supplementary Note 1-2 for a new printing apparatus 1y, wherein the new printing apparatus 1y includes a new drive control unit 5y including a new circuit substrate 500y, a new aluminum electrolytic capacitor Cdy disposed on the new circuit substrate 500y, and a new fan FNy disposed on the new circuit substrate 500y, and a new head unit 3y that is controlled by the new drive control unit 5y, and a used electronic apparatus 1x includes a used drive control unit 5x that includes a used circuit substrate 500x, a used aluminum electrolytic capacitor Cdx disposed on the used circuit substrate 500x and having a same function as the new aluminum electrolytic capacitor Cdy, and a used fan FNx disposed on the used circuit substrate 500x and having a same function as the new fan FNy, and has a same function as the new drive control unit 5y, and a used head unit 3x that is controlled by the used drive control unit 5x and has a same function as the new head unit 3y, the manufacturing management system Sys including: an information acquiring section 911 that acquires, from the used printing apparatus 1x, energization time information DC indicating an energization time TC for the used printing apparatus 1x, and printing time information DF indicating a printing time TF of the used head unit 3x; a replacement necessity determining section 912 that determines necessity of replacement of the used aluminum electrolytic capacitor Cdx by using a threshold TthC for the energization time TC for the used printing apparatus 1x, and the energization time information DC, and determines necessity of replacement of the used fan FNx by using a threshold TthF for the printing time TF of the used printing apparatus 1x, and the printing time information DF; and a reuse determining section 913 that determines to manufacture the new printing apparatus 1y in which a quality assurance period of the new printing apparatus 1y is set to be shorter than a quality assurance period of the used printing apparatus 1x at time of shipment of the used printing apparatus 1x, by using the used drive control unit 5x included in the used printing apparatus 1x as the new drive control unit 5y, if the replacement necessity determining section 912 determines that the used aluminum electrolytic capacitor Cdx does not need to be replaced and that the used fan FNx does not need to be replaced, and that determines to manufacture the new printing apparatus 1y in which the quality assurance period of the new printing apparatus 1y is set to be shorter than the quality assurance period of the used printing apparatus 1x at the time of the shipment of the used printing apparatus 1x, by newly disposing the new aluminum electrolytic capacitor Cdy on the used circuit substrate 500x after the used aluminum electrolytic capacitor Cdx is removed from the used circuit substrate 500x, using the used fan FNx disposed on the used circuit substrate 500x as the new fan FNy, and using, as the new circuit substrate 500y, the used circuit substrate 500x after the new aluminum electrolytic capacitor Cdy is disposed, if the replacement necessity determining section 912 determines that the used aluminum electrolytic capacitor Cdx needs to be replaced and that the used fan FNx does not need to be replaced.

### Supplementary Note 1-3

There is provided a manufacturing management system Sys according to Supplementary Note 1-3 for a new printing apparatus 1y, wherein the new printing apparatus 1y includes a new drive control unit 5y including a new circuit substrate 500y, a new aluminum electrolytic capacitor Cdy disposed on the new circuit substrate 500y, and a new fan FNy disposed on the new circuit substrate 500y, and a new head unit 3y that is controlled by the new drive control unit 5y, and a used electronic apparatus 1x includes a used drive control unit 5x that includes a used circuit substrate 500x, a used aluminum electrolytic capacitor Cdx disposed on the used circuit substrate 500x and having a same function as the new aluminum electrolytic capacitor Cdy, and a used fan FNx disposed on the used circuit substrate 500x and having a same function as the new fan FNy, and has a same function as the new drive control unit 5y, and a used head unit 3x that is controlled by the used drive control unit 5x and has a same function as the new head unit 3y, the manufacturing management system Sys including: an information acquiring section 911 that acquires, from the used printing apparatus 1x, energization time information DC indicating an energization time TC for the used printing apparatus 1x, and printing time information DF indicating a printing time TF of the used head unit 3x; a replacement necessity determining section 912 that determines necessity of replacement of the used aluminum electrolytic capacitor Cdx by using a threshold TthC for the energization time TC for the used printing apparatus 1x, and the energization time information DC, and determines necessity of replacement of the used fan FNx by using a threshold TthF for the printing time TF of the used printing apparatus 1x, and the printing time information DF; and a reuse determining section 913 that determines to manufacture the new printing apparatus 1y in which a quality assurance period of the new printing apparatus 1y is set to be shorter than a quality assurance period of the used printing apparatus 1x at time of shipment of the used printing apparatus 1x, by using the used drive control unit 5x included in the used printing apparatus 1x as the new drive control unit 5y, if the replacement necessity determining section 912 determines that the used aluminum electrolytic capacitor Cdx does not need to be replaced and that the used fan FNx does not need to be replaced, and that determines to manufacture the new printing apparatus 1y in which the quality assurance period of the new printing apparatus 1y is set to be shorter than the quality assurance period of the used printing apparatus 1x at the time of the shipment of the used printing apparatus 1x, by newly disposing the new fan FNy on the used circuit substrate 500x after the used fan FNx is removed from the used circuit substrate 500x, using the used aluminum electrolytic capacitor Cdx disposed on the used circuit substrate 500x as the new aluminum electrolytic capacitor Cdy, and using, as the new circuit substrate 500y, the used circuit substrate 500x after the new fan FNy is disposed, if the replacement necessity determining section 912 determines that the used aluminum electrolytic capacitor Cdx does not need to be replaced and that the used fan FNx needs to be replaced.

### Supplementary Note 1-4

A manufacturing management system Sys according to Supplementary Note 1-4 is the manufacturing management system Sys according to any one of Supplementary Notes 1-1 to 1-3, wherein the reuse determining section 913 determines to manufacture the new printing apparatus 1y without using the used drive control unit 5x included in the used printing apparatus 1x, if the replacement necessity determining section 912 determines that the used aluminum electrolytic capacitor Cdx needs to be replaced, by using the threshold TthC, and the replacement necessity determining section 912 determines that the used fan FNx needs to be replaced, by using the threshold TthF.

### Supplementary Note 1-5

A manufacturing management system Sys according to Supplementary Note 1-5 is the manufacturing management system Sys according to any one of Supplementary Notes 1-1 to 1-4, wherein, if the used circuit substrate 500x is contaminated or damaged, the reuse determining section 913 determines to manufacture the new printing apparatus 1y without using the used drive control unit 5x included in the used printing apparatus 1x.

### Supplementary Note 1-6

A manufacturing management system Sys according to Supplementary Note 1-6 is the manufacturing management system Sys according to any one of Supplementary Notes 1-1 to 1-5, and further includes an inspection apparatus 82 that inspects internal wiring of the used circuit substrate 500x, wherein the reuse determining section 913 determines to manufacture the new printing apparatus 1y without using the used drive control unit 5x included in the used printing apparatus 1x if standard inspection result information DK1 indicating a result of the inspection by the inspection apparatus 82 indicates that a possibility that the internal wiring of the used circuit substrate 500x is damaged is greater than or equal to a certain value.

In Supplementary Note 1, the inspection apparatus 82 is an example of an “inspection section”.

### C.2. Supplementary Note 2

A printing apparatus 1 according to Supplementary Note 2 will be described.

### Supplementary Note 2-1

A printing apparatus 1 according to Supplementary Note 2-1 including a circuit substrate 500 and including a signal through-hole HLc through which a drive signal Com for driving the printing apparatus 1 is supplied, a reference through-hole HLb set to a ground electrical potential, and a standard inspection through-hole HLk1 to which a signal is not supplied when the printing apparatus 1 is used, wherein a distance LK1 between the reference through-hole HLb and the standard inspection through-hole HLk1 is shorter than a distance Lbc between the reference through-hole HLb and the signal through-hole HLc.

In Supplementary Note 2, the printing apparatus 1 is an example of the “electronic apparatus”, the standard inspection through-hole HLk1 is an example of a “first inspection through-hole”, the drive signal Com is an example of an “electrical signal”, and the ground electrical potential is an example of a “reference electrical potential”.

According to Supplementary Note 2-1, according to the present modification, the distance between the standard inspection through-hole HLk1 and the reference through-hole HLb is shorter than the distance between the standard inspection through-hole HLk1 and the signal through-hole HLc in the circuit substrate 500. Therefore, for the reuse of the circuit substrate 500, the degree of growth of a dendrite DN in the circuit substrate 500 can be inspected.

### Supplementary Note 2-2

A printing apparatus 1 according to Supplementary Note 2-2 is the printing apparatus 1 according to Supplementary Note 2-1, wherein the circuit substrate 500 includes a digital drive region Ar1 where a digital signal flows and an analog drive region Ar2 where an analog signal flows, and the reference through-hole HLb and the standard inspection through-hole HLk1 are disposed in the analog drive region Ar2.

In Supplementary Note 2, the digital signal is an example of a “signal having a first voltage”, the analog signal is an example of a “signal having a second voltage”, the digital drive region Ar1 is an example of a “first region”, and the analog drive region Ar2 is an example of a “second region”.

### Supplementary Note 2-3

A printing apparatus 1 according to Supplementary Note 2-3 is the printing apparatus 1 according to Supplementary Note 2-1 or 2-2, wherein the circuit substrate 500 includes an outer peripheral region AG including an outer periphery EG of the circuit substrate 500, and the standard inspection through-hole HLk1 is disposed in the outer peripheral region AG.

### Supplementary Note 2-4

A printing apparatus 1 according to Supplementary Note 2-4 is the printing apparatus 1 according to any one of Supplementary Notes 2-1 to 2-3, wherein the circuit substrate 500 has a polygonal shape, and the standard inspection through-hole HLk1 is disposed in an end portion region AGxy including a corner of the circuit substrate 500.

### Supplementary Note 2-5

A printing apparatus 1 according to Supplementary Note 2-5 is the printing apparatus 1 according to any one of Supplementary Notes 2-1 to 2-4, and further includes a strict inspection through-hole HLk2 to which a signal is not supplied when the printing apparatus 1 is used, wherein a distance LK2 between the reference through-hole HLb and the strict inspection through-hole HLk2 is shorter than the distance LK1 between the reference through-hole HLb and the standard inspection through-hole HLk1.

In Supplementary Note 2, the strict inspection through-hole HLk2 is an example of a “second inspection through-hole”.

According to Supplementary Note 2-5, in addition to a standard substrate inspection for checking conduction between the reference through-hole HLb and the standard inspection through-hole HLk1, a strict substrate inspection for checking conduction between the reference through-hole HLb and the strict inspection through-hole HLk2 can be performed. Therefore, as compared to an aspect in which the strict substrate inspection cannot be performed, it is possible to accurately determine the degree of degradation of the circuit substrate 500 in multiple stages, and accurately estimate the remaining assurance period of the circuit substrate 500 in multiple stages.

What is claimed is:

1. An electronic apparatus comprising a circuit substrate, wherein
the circuit substrate includes
a signal through-hole through which an electrical signal for driving the electronic apparatus is supplied,
a reference through-hole set to a reference electrical potential, and
a first inspection through-hole to which a signal is not supplied when the electronic apparatus is used, and
a distance between the reference through-hole and the first inspection through-hole is shorter than a distance between the reference through-hole and the signal through-hole.

2. The electronic apparatus according to claim 1, wherein
the circuit substrate includes
a first region where a signal having a first voltage flows, and
a second region where a signal having a second voltage higher than the first voltage flows, and
the reference through-hole and the first inspection through-hole are disposed in the second region.

3. The electronic apparatus according to claim 1, wherein
the circuit substrate includes
an outer peripheral region including an outer periphery of the circuit substrate, and
the first inspection through-hole is disposed in the outer peripheral region.

4. The electronic apparatus according to claim 1, wherein
the circuit substrate has a polygonal shape, and
the first inspection through-hole is disposed in an end portion region included in the circuit substrate and including a corner of the circuit substrate having the polygonal shape.

5. The electronic apparatus according to claim 1, further comprising
a second inspection through-hole to which a signal is not supplied when the electronic apparatus is used, wherein
a distance between the reference through-hole and the second inspection through-hole is shorter than the distance between the reference through-hole and the first inspection through-hole.

6. A print head comprising a circuit substrate, wherein
the circuit substrate includes
a signal through-hole through which an electrical signal for driving the print head is supplied,
a reference through-hole set to a reference electrical potential, and
a first inspection through-hole to which a signal is not supplied when the print head is used, and
a distance between the reference through-hole and the first inspection through-hole is shorter than a distance between the reference through-hole and the signal through-hole.

7. The print head according to claim 6, wherein
the circuit substrate includes
a first region where a signal having a first voltage flows, and
a second region where a signal having a second voltage higher than the first voltage flows, and
the reference through-hole and the first inspection through-hole are disposed in the second region.

8. The print head according to claim 6, wherein
the circuit substrate includes an outer peripheral region including an outer periphery of the circuit substrate, and
the first inspection through-hole is disposed in the outer peripheral region.

9. The print head according to claim 6, wherein
the circuit substrate has a polygonal shape, and
the first inspection through-hole is disposed in an end portion region included in the circuit substrate and including a corner of the circuit substrate having the polygonal shape.

10. The print head according to claim 6, further comprising
a second inspection through-hole to which a signal is not supplied when the print head is used, wherein
a distance between the reference through-hole and the second inspection through-hole is shorter than the distance between the reference through-hole and the first inspection through-hole.

11. The print head according to claim 6, further comprising
an ejection section that ejects liquid, wherein a flexible printed circuit substrate that transmits an electrical signal to the ejection section is coupled to the circuit substrate.

12. A method for manufacturing an electronic apparatus including a first circuit substrate,
another electronic apparatus including a second circuit substrate having a same function as the first circuit substrate, the method comprising:
if conduction between a reference through-hole disposed in the second circuit substrate and set to a reference electrical potential and a first inspection through-hole that is disposed in the second circuit substrate and to which a signal is not supplied when the other electronic apparatus is used is not confirmed, manufacturing the electronic apparatus by using the second circuit substrate as the first circuit substrate; and
if the conduction between the reference through-hole and the first inspection through-hole is confirmed, manufacturing the electronic apparatus without using the second circuit substrate, wherein
a distance between the reference through-hole and the first inspection through-hole is shorter than a distance between the reference through-hole and a signal through-hole through which an electrical signal for driving the electronic apparatus is supplied.

13. The method according to claim 12, wherein
the second circuit substrate includes a second inspection through-hole to which a signal is not supplied when the other electronic apparatus is used, and
a quality assurance period of the electronic apparatus in a case where conduction between the reference through-hole and the second inspection through-hole is not confirmed and the electronic apparatus is to be manufactured by using the second circuit substrate as the first circuit substrate is set to be longer than a quality assurance period of the electronic apparatus in a case where the conduction between the reference through-hole and the second inspection through-hole is confirmed and the electronic apparatus is to be manufactured by using the second circuit substrate as the first circuit substrate.
